(19) United States
(12) Patent Application Publication
(10) Pub. No.: US 2025/0233091 A1
(43) Pub. Date: Jul. 17, 2025

(54) INTEGRATED BONDING PADS WITH CONVEX SIDEWALLS AND METHODS FOR FORMING THE SAME

(71) Applicant: SANDISK TECHNOLOGIES LLC, ADDISON, TX (US)

(72) Inventors: Adarsh Rajashekhar, Santa Clara, CA (US); Hiroyuki Kinoshita, San Jose, CA (US); Senaka Kanakamedala, San Jose, CA (US)

(21) Appl. No.: 18/413,687

(22) Filed: Jan. 16, 2024

(51) Int. Cl. H01L 23/00

(52) U.S. Cl. CPC H01L 24/05; H01L 24/03; H01L 24/06; H01L 24/08; H01L 24/80; H01L 2224/0345; H01L 2224/03452; H01L 2224/03462; H01L 2224/03464; H01L 2224/03614; H01L 2224/03845; H01L 2224/05186; H01L 2224/05559; H01L 2224/05571; H01L 2224/05624; H01L 2224/05647; H01L 2224/05657; H01L 2224/05676; H01L 2224/0568; H01L 2224/05684; H01L 2224/0603; H01L 2224/06131; H01L 2224/06517; H01L 2224/80357; H01L 2224/80379; H01L 2224/80896; H01L 2924/0132; H01L 2924/04541; H01L 2924/0455; H01L 2924/04563; H01L 2924/04941; H01L 2924/04953; H01L 2924/0496; H01L 2924/059

(57) ABSTRACT

A semiconductor die includes semiconductor devices located over a substrate, metal interconnect structures embedded in dielectric material layers that overlie the semiconductor devices, a bonding-level dielectric layer that overlies the dielectric material layers, and an array of integrated metal bonding pads embedded within the bonding-level dielectric layer and electrically connected to a respective one of the metal interconnect structures. Each of the integrated metal bonding pads includes a respective metallic via portion that extends through a lower portion of the bonding-level dielectric layer, and a respective metallic pad portion having a convex sidewall that extends through an upper portion of the bonding-level dielectric layer.

### FIELD

The present disclosure relates generally to the field of semiconductor devices, and particularly to semiconductor dies including integrated bonding pads with convex sidewalls and methods for forming the same.

### BACKGROUND

Metal-to-metal bonding may be used to provide electrical connection between a mating pair of semiconductor dies having opposing bonding pads. However, methods of making bonding pads typically utilize a number of steps.

### SUMMARY

According to an aspect of the present disclosure, a semiconductor structure comprising a first semiconductor die is provided. The first semiconductor die comprises: first semiconductor devices located over a first substrate; first metal interconnect structures embedded in first dielectric material layers that overlie the first semiconductor devices; a first bonding-level dielectric layer that overlies the first dielectric material layers; and an array of first integrated metal bonding pads embedded within the first bonding-level dielectric layer and electrically connected to a respective one of the first metal interconnect structures, wherein each of the first integrated metal bonding pads comprises: a respective metallic via portion that extends through a lower portion of the first bonding-level dielectric layer; and a respective metallic pad portion having a convex sidewall that extends through an upper portion of the first bonding-level dielectric layer.

According to another aspect of the present disclosure, a method of forming a semiconductor structure is provided. The method comprises: forming first semiconductor devices over a first substrate; forming first dielectric material layers embedding first metal interconnect structures over the first semiconductor devices, wherein the first metal interconnect structures are electrically connected to the first semiconductor devices; forming a first bonding-level dielectric layer over the first dielectric material layer; forming an etch mask layer comprising an array of discrete openings therethrough over the first bonding-level dielectric material layer; forming pad cavities in an upper portion of the first bonding-level dielectric layer underneath the openings in the etch mask layer by performing an isotropic etch process; forming via cavities in a lower portion of the first bonding-level dielectric layer by performing an anisotropic etch process though the pad cavities while the etch mask layer is present; removing the etch mask layer; and forming an array of first integrated metal bonding pads within a combination of the pad cavities and the via cavities.

### BRIEF DESCRIPTION OF THE DRAWINGS

FIGS. 1A, 1B, 1D, 1E, 1F, 1H, and 1I are sequential vertical cross-sectional views of a first exemplary structure during formation of a first bonded assembly of a first semiconductor die and a second semiconductor die according to an embodiment of the present disclosure. FIG. 1C is a top-down view of the first exemplary structure of FIG. 1B. The vertical plane B-B′ in FIG. 1C is the cut plane of the vertical cross-sectional view of FIG. 1B. FIG. 1G is a top-down view of the first exemplary structure of FIG. 1F. The vertical plane F-F′ in FIG. 1G is the cut plane of the vertical cross-sectional view of FIG. 1F.

FIG. 1J is a vertical cross-sectional view of a second semiconductor die.

FIG. 1K is a vertical cross-sectional view of a first bonded assembly of the first semiconductor die and the second semiconductor die.

FIG. 1L is a vertical cross-sectional view of an alternative configuration of the first semiconductor die.

FIG. 1M is a vertical cross-sectional view of an alternative configuration of the first bonded assembly.

FIG. 2A is a vertical cross-sectional view of a second semiconductor die.

FIG. 2B is a vertical cross-sectional view of a second bonded assembly of a first semiconductor die and the second semiconductor die.

FIG. 3 is a vertical cross-sectional view of a third bonded assembly of a first semiconductor die and a second semiconductor die.

FIGS. 4A, 4B, 4D, 4E, 4F, 4H, and 4I are sequential vertical cross-sectional views of a first exemplary structure during formation of a fourth bonded assembly of a first semiconductor die and a second semiconductor die according to an embodiment of the present disclosure. FIG. 4C is a top-down view of the first exemplary structure of FIG. 4B. The vertical plane B-B′ in FIG. 4C is the cut plane of the vertical cross-sectional view of FIG. 4B. FIG. 4G is a top-down view of the first exemplary structure of FIG. 4F. The vertical plane F-F′ in FIG. 4G is the cut plane of the vertical cross-sectional view of FIG. 4F.

FIG. 4J is a vertical cross-sectional view of a second semiconductor die.

FIG. 4K is a vertical cross-sectional view of a fourth bonded assembly of the first semiconductor die and the second semiconductor die.

FIG. 5A is a vertical cross-sectional view of a second semiconductor die.

FIG. 5B is a vertical cross-sectional view of a fifth bonded assembly of a first semiconductor die and the second semiconductor die.

FIG. 6 is a vertical cross-sectional view of a sixth bonded assembly of a first semiconductor die and a second semiconductor die.

FIGS. 7A, 7B, 7D, 7E, 7F, 7H, and 7I are sequential vertical cross-sectional views of a first exemplary structure during formation of a seventh bonded assembly of a first semiconductor die and a second semiconductor die according to an embodiment of the present disclosure. FIG. 7C is a top-down view of the first exemplary structure of FIG. 7B. The vertical plane B-B′ in FIG. 7C is the cut plane of the vertical cross-sectional view of FIG. 7B. FIG. 7G is a top-down view of the first exemplary structure of FIG. 7F. The vertical plane F-F′ in FIG. 7G is the cut plane of the vertical cross-sectional view of FIG. 7F.

FIG. 7J is a vertical cross-sectional view of a second semiconductor die.

FIG. 7K is a vertical cross-sectional view of a seventh bonded assembly of the first semiconductor die and the second semiconductor die.

FIG. 7L is a vertical cross-sectional view of an alternative configuration of the first semiconductor die.

FIG. 7M is a vertical cross-sectional view of an alternative configuration of the seventh bonded assembly.

FIG. 8A is a vertical cross-sectional view of a second semiconductor die.

FIG. 8B is a vertical cross-sectional view of an eighth bonded assembly of a first semiconductor die and the second semiconductor die.

FIG. 9 is a vertical cross-sectional view of a ninth bonded assembly of a first semiconductor die and a second semiconductor die.

FIGS. 10A, 10B, 10D, 10E, 10F, 10H, and 10I are sequential vertical cross-sectional views of a first exemplary structure during formation of a tenth bonded assembly of a first semiconductor die and a second semiconductor die according to an embodiment of the present disclosure. FIG. 10C is a top-down view of the first exemplary structure of FIG. 10B. The vertical plane B-B′ in FIG. 10C is the cut plane of the vertical cross-sectional view of FIG. 10B. FIG. 10G is a top-down view of the first exemplary structure of FIG. 10F. The vertical plane F-F′ in FIG. 10G is the cut plane of the vertical cross-sectional view of FIG. 10F.

FIG. 10J is a vertical cross-sectional view of a second semiconductor die.

FIG. 10K is a vertical cross-sectional view of a tenth bonded assembly of the first semiconductor die and the second semiconductor die.

FIG. 11A is a vertical cross-sectional view of a second semiconductor die.

FIG. 11B is a vertical cross-sectional view of an eleventh bonded assembly of a first semiconductor die and the second semiconductor die.

FIG. 12 is a vertical cross-sectional view of a twelfth bonded assembly of a first semiconductor die and a second semiconductor die.

### DETAILED DESCRIPTION

The embodiments of the present disclosure are directed to semiconductor dies including integrated bonding pads with convex sidewalls and methods for forming the same, of which various aspects are now described in detail. The embodiments of the present disclosure can be employed to form semiconductor devices, such as three-dimensional memory devices comprising a plurality of memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or from each other, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exists a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the first continuous structure. For example, a layer may be located between any pair of horizontal planes between, or at, a top surface and a bottom surface of the first continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

As used herein, a “memory level” or a “memory array level” refers to the level corresponding to a general region between a first horizontal plane (i.e., a plane parallel to the top surface of the substrate) including topmost surfaces of an array of memory elements and a second horizontal plane including bottommost surfaces of the array of memory elements. As used herein, a “through-stack” element refers to an element that vertically extends through a memory level.

As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10^{-5 S/m to} 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made at the standard condition.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded throughout, for example, by flip-chip bonding or another chip-to-chip bonding. A package or a chip may include a single semiconductor die (or a “die”) or a plurality of semiconductor dies. A die is the smallest unit that may independently execute external commands or report status. Typically, a package or a chip with multiple dies is capable of simultaneously executing as many number of external commands as the total number of dies therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

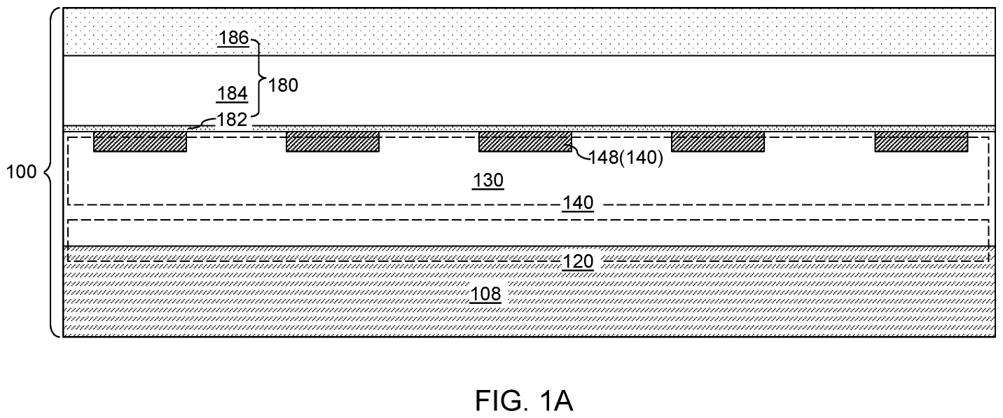

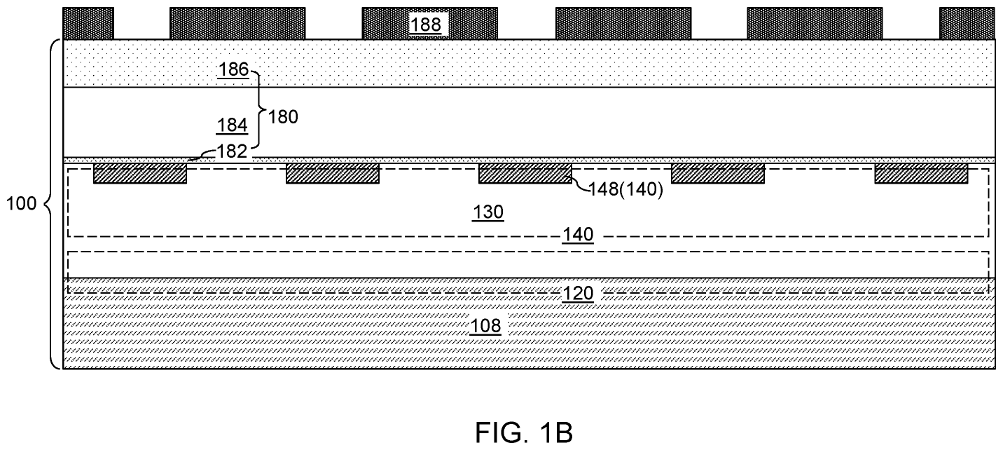

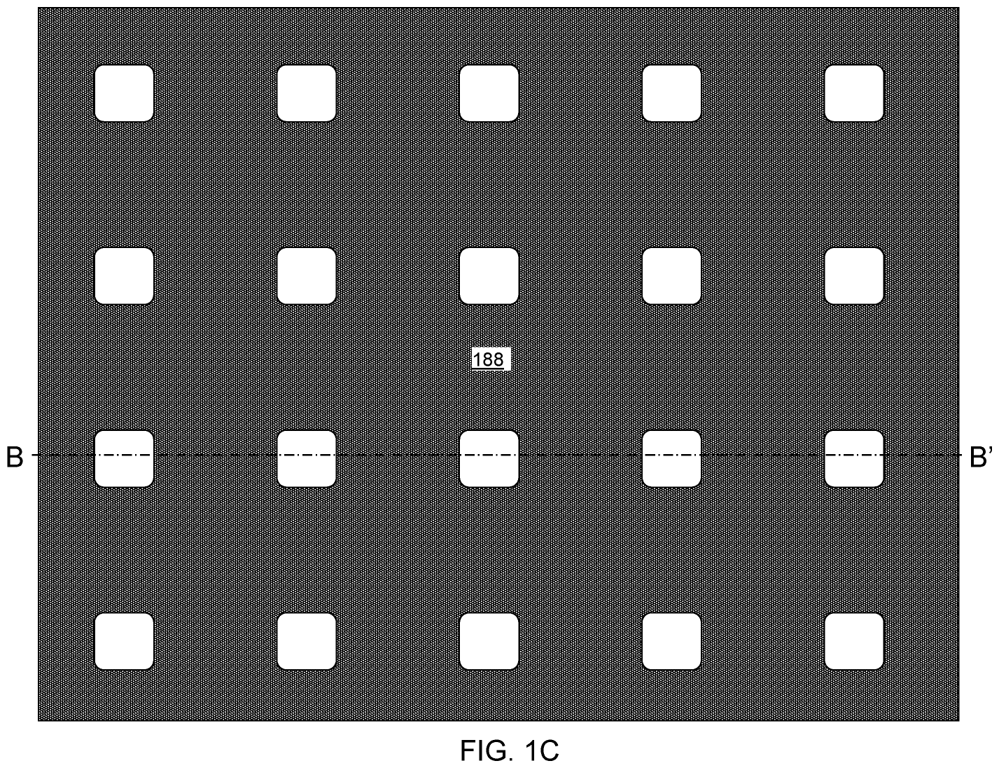

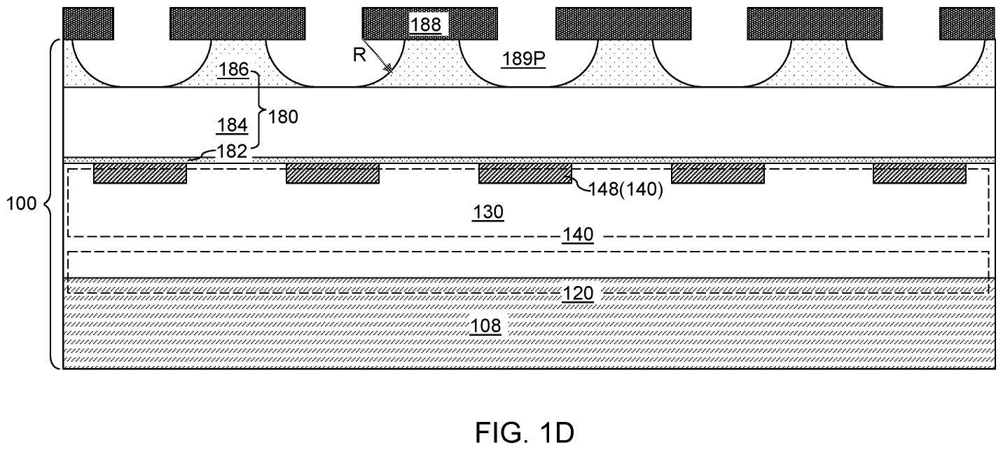

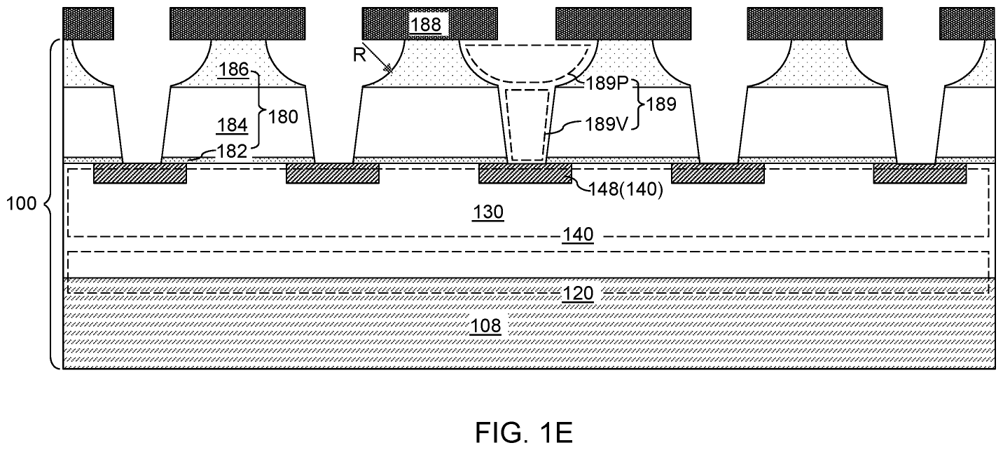

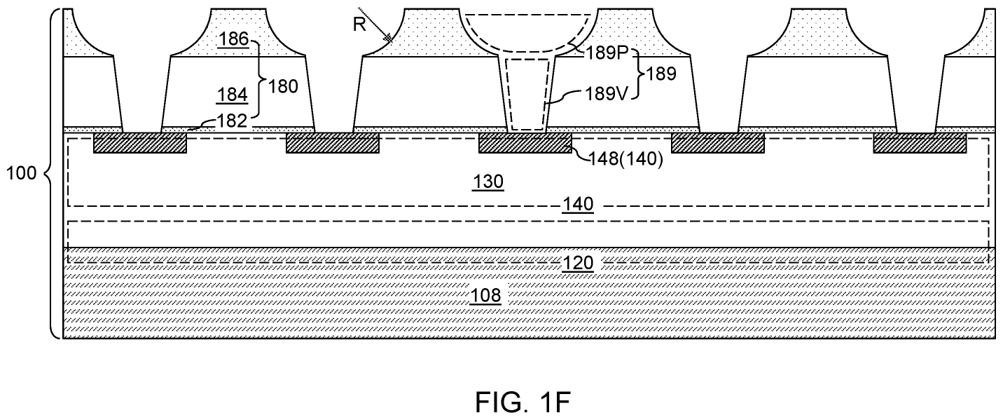

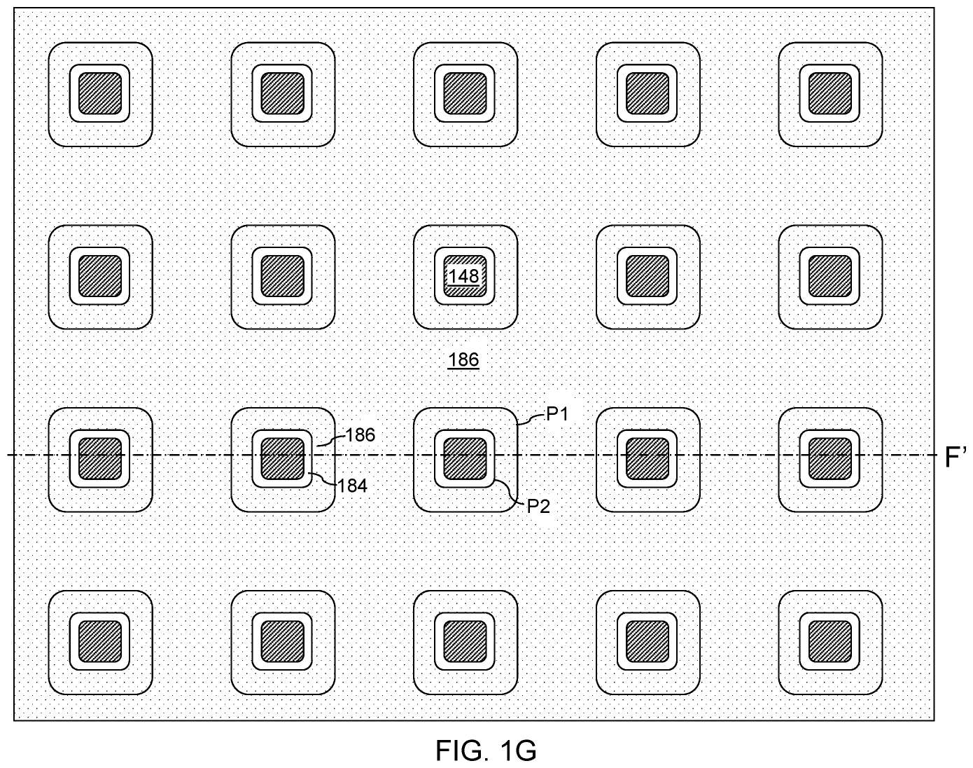

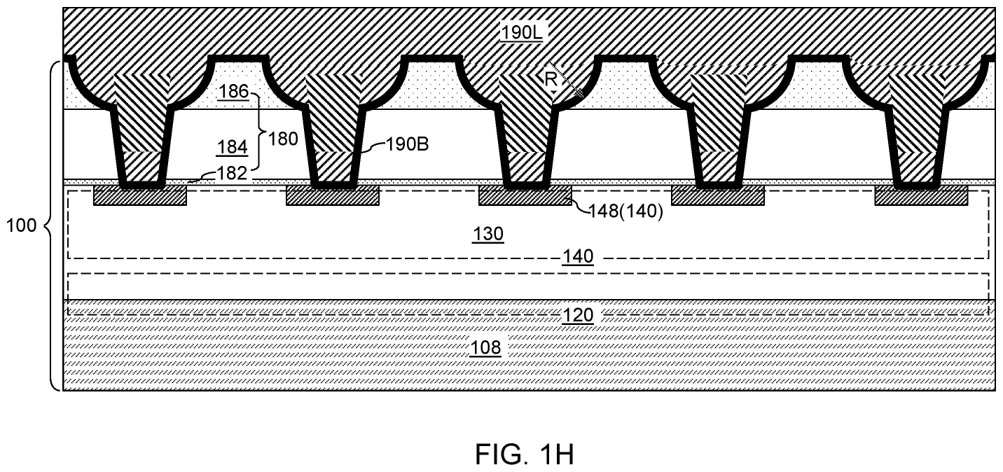

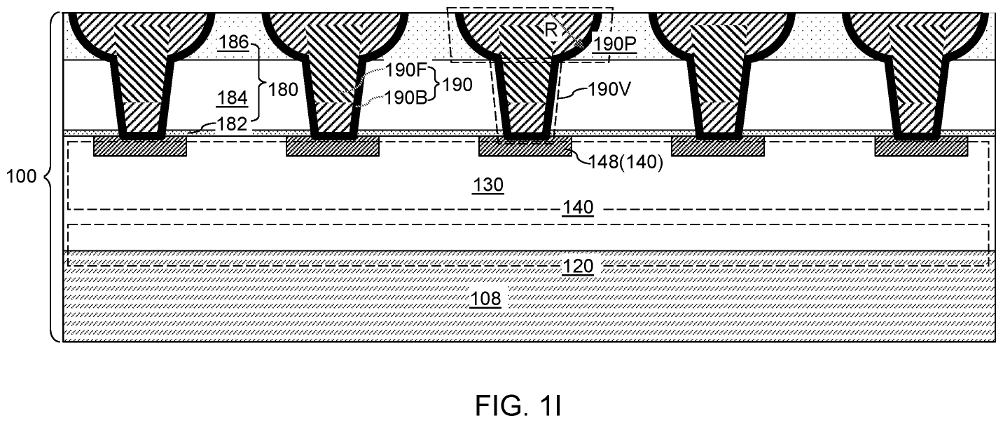

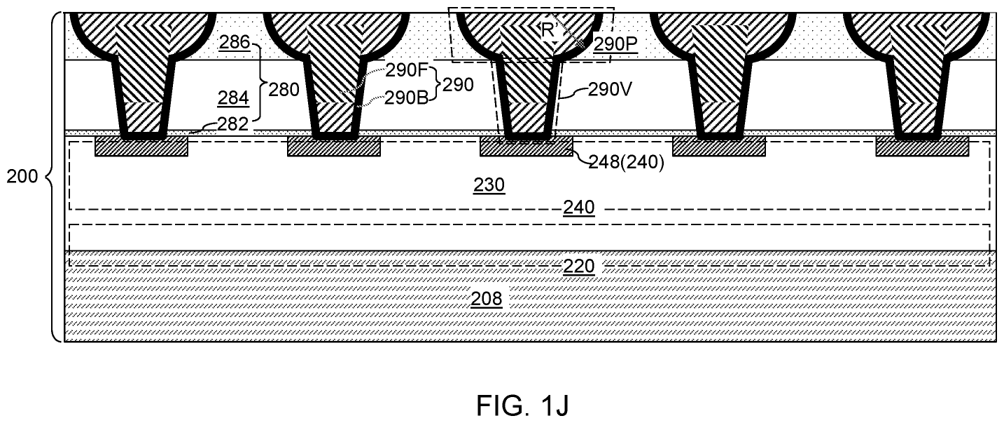

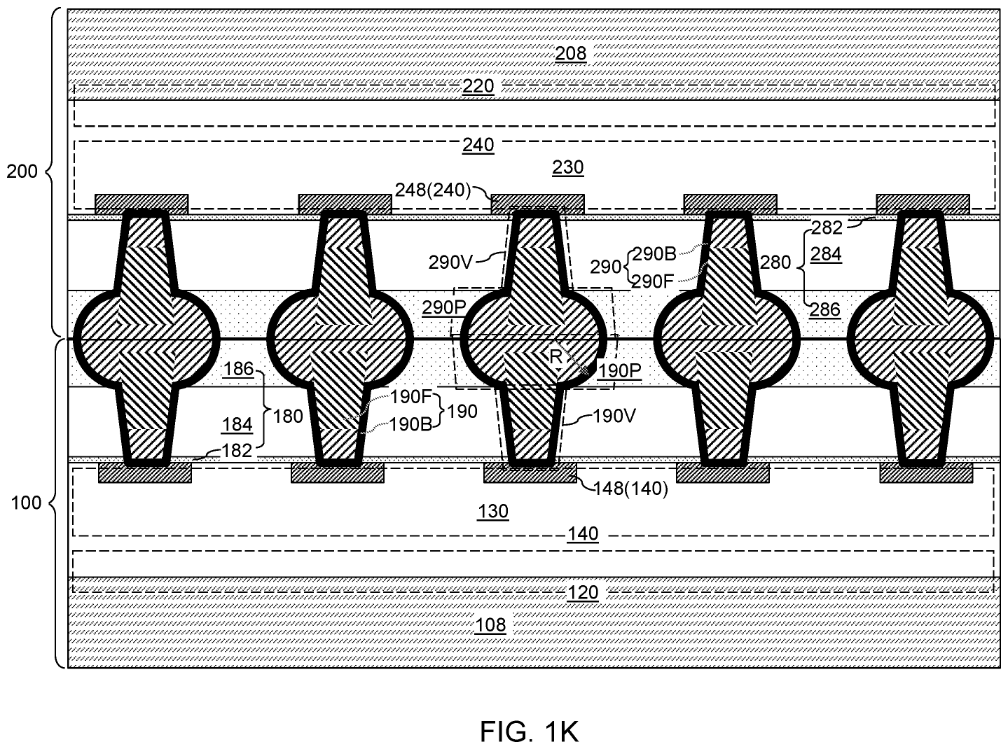

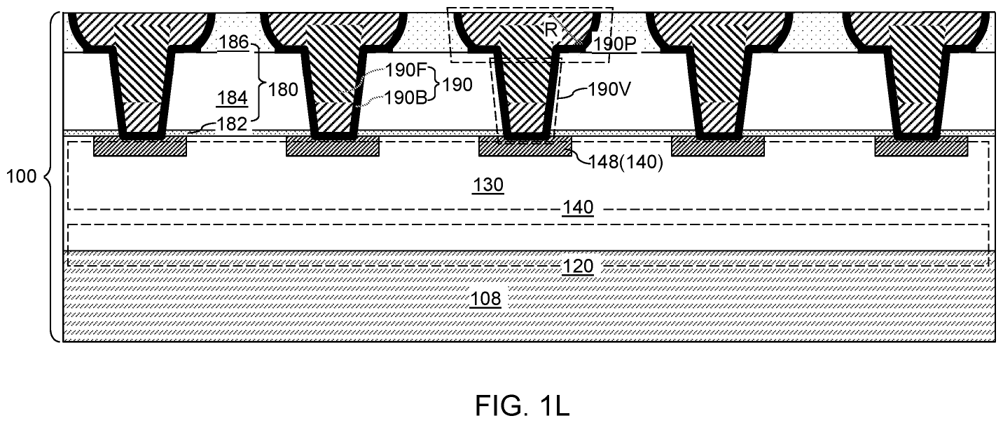

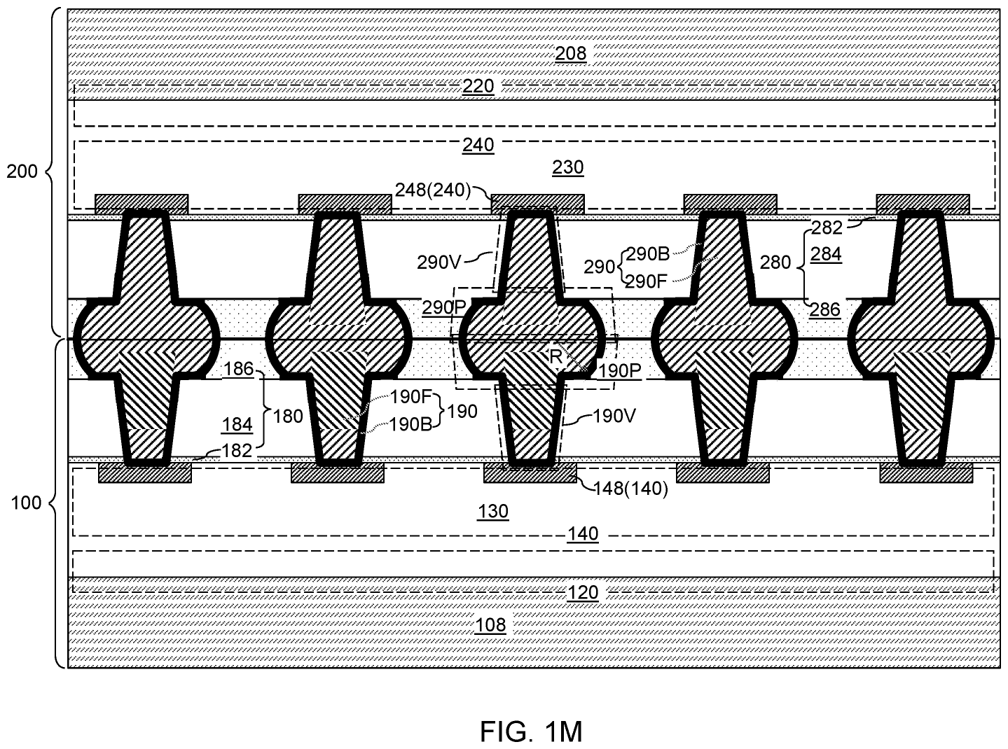

Referring to FIG. 1A, a first semiconductor die 100 according to an embodiment of the present disclosure is illustrated. The first semiconductor die comprises a first substrate 108, first semiconductor devices 120 formed on, over and/or in the first substrate 108, first dielectric material layers 130 that are formed over the first semiconductor devices 120 and embedding first metal interconnect structures 140, and a first bonding-level dielectric layer 180 that is formed over the first dielectric material layers 130.

The first substrate 108 may comprise a semiconductor substrate, such as a single-crystalline silicon substrate or a semiconductor-on-insulator substrate including a single-crystalline semiconductor layer at least at an upper portion thereof. In one embodiment, the first substrate 108 may comprise a commercially available single-crystalline silicon substrate on which a two-dimensional array of memory dies are formed. In some embodiments, the first substrate 108 may be a carrier substrate which is subsequently removed (for example, by grinding, polishing, and/or by etching) from the first semiconductor devices 120 after the first semiconductor die 100 is bonded to a second semiconductor die.

The first semiconductor devices 120 may comprise any type of semiconductor devices known in the art. Generally, the first semiconductor devices 120 may comprise logic devices (such as CMOS transistors), memory devices (such as a two-dimensional memory array or a three-dimensional memory array including alternating stacks of insulating layers and electrically conductive layers and vertical stacks of memory elements and vertical semiconductor channels vertically extending through a respective one of the alternating stacks), or any other type of semiconductor device.

The first metal interconnect structures 140 may comprise metal line structures and metallic via structures. The general location of the first metal interconnect structures 140 is represented by a dotted rectangle, and that structural details of the first metal interconnect structures 140 are not illustrated in the drawings for clarity. The first metal interconnect structures 140 may have any configuration known in the art. In some embodiments, combinations of a metal line structure and at least one metallic via structure may be formed as integrated metal line-and-via structures. The first metal interconnect structures 140 can be electrically connected to the first semiconductor devices 120. The first metal interconnect structures 140 can provide electrical connection between the first semiconductor devices 120, and between the first semiconductor devices 120 and the first metallic bonding structures to be subsequently formed in the first bonding-level dielectric layer 180. First topmost metal interconnect structures 148, which are a subset of the first metal interconnect structures 140, are illustrated. In one embodiment, the first topmost metal interconnect structures 148 may have the same pattern as the pattern of a two-dimensional array of first metallic bonding structures to be subsequently formed in the first bonding-level dielectric layer 180. In one embodiment, the first topmost metal interconnect structures 148 may be arranged in a pattern of a rectangular array or in a pattern of a hexagonal array.

In one embodiment, the first bonding-level dielectric layer 180 comprises a first etch-stop dielectric layer 182, a first silicate glass (i.e., silicon oxide) layer 184, and a first silicon carbide nitride (i.e., silicon carbonitride) layer 186. The first etch-stop dielectric layer 182 comprises a dielectric material that can be employed as an etch-stop structure. For example, the first etch-stop dielectric layer 182 may comprise silicon nitride, silicon carbide, silicon carbide nitride (i.e., silicon carbonitride) and/or a dielectric metal oxide. The thickness of the first etch- stop dielectric layer 182 may be in a range from 10 nm to 50 nm, although lesser and greater thicknesses may also be employed. The first silicate glass layer 184 comprises a silicate glass material, such as undoped silicate glass (i.e., silicon oxide) or a doped silicate glass. The first silicate glass layer 184 may be deposited by chemical vapor deposition. The thickness of the first silicate glass layer 184 may be in a range from 100 nm to 2,000 nm, such as from 300 nm to 1,000 nm, although lesser and greater thicknesses may also be employed.

The first silicon carbide nitride layer 186 comprises, and/or consists essentially of, silicon carbide nitride (i.e., silicon carbonitride). Silicon carbide nitride refers to a dielectric material composed of silicon, carbon, and nitrogen. The atomic percentage of silicon atoms in silicon carbide nitride may be in a range from 20% to 40%; the atomic percentage of carbon atoms in silicon carbide nitride may be in a range from 10% to 40%, and the atomic percentage of nitrogen atoms in silicon carbide nitride may be in a range from 10% to 40%. The first silicon carbide nitride layer 186 may be deposited by chemical vapor deposition. The thickness of the first silicon carbide nitride layer 186 may be in a range from 100 nm to 2,000 nm, such as from 300 nm to 1,000 nm, although lesser and greater thicknesses may also be employed.

Referring to FIGS. 1B and 1C, an etch mask layer 188 can be formed over the first silicon carbide nitride layer 186. The etch mask layer 188 may comprise a carbon-based material, a conductive material or an insulating material, and may have a thickness in a range from 50 nm to 200 nm, although lesser and greater thicknesses may also be employed. In one embodiment, the etch mask layer 188 may comprise and/or may consist essentially of the carbon-based material including carbon at an atomic percentage greater than 80%. In an illustrative example, the etch mask layer 188 may comprise and/or may consist essentially of amorphous carbon, diamond-like carbon, or a doped carbon. Alternatively, the etch mask layer 188 may include a bilayer of a lower carbon-based material sublayer and an upper silicate glass (e.g., spin-on glass) sublayer. Yet alternatively, the etch mask layer 188 may comprise a metallic material, such as titanium nitride.

The etch mask layer 188 can be patterned to form an array of discrete openings therethrough. For example, a photoresist layer (not shown) can be applied over the etch mask layer 188, and can be lithographically patterned to form openings therein. An anisotropic etch process can be performed to transfer the pattern of the openings in the photoresist layer through the etch mask layer 188. In one embodiment, the pattern of the discrete openings in the etch mask layer 188 may be the same as the pattern of the first topmost metal interconnect structures 148. In one embodiment each opening in the etch mask layer 188 may be formed entirely within the area of a respective underlying first topmost metal interconnect structure 148. The photoresist layer may be removed, for example, by ashing.

Referring to FIG. 1D, an isotropic etch process can be performed to isotropically etch the material of the first silicon carbide nitride layer 186 selective to the material of the etch mask layer 188. In one embodiment, a wet etch process employing an etch chemistry that etches silicon carbide nitride selective to silicon oxide can be employed, such as wet etch chemistries employing one or more of hot phosphoric acid, potassium hydroxide, tetramethylammonium hydroxide (TMAH), and organic solvents such as n-methyl-2-pyrrolidone (NMP) or dimethyl sulfoxide (DMSO). In one embodiment, the isotropic etch process may etch the material of the first silicon carbide nitride layer 186 selective to the material of the first silicate glass layer 184. As used herein, an etch process that etches a first material is selective to a second material if the etch rate of the first material during the etch process is at least 3 times the etch rate of the second material during the etch process. As used herein, a “selectivity” of an etch process that etches a first material with respective to a second material is defined as the ratio of the etch rate of the first material to the etch rate of the second material.

Pad cavities 189P are formed in an upper portion of the first bonding-level dielectric layer 180 underneath the discrete openings in the etch mask layer 188 by performing the isotropic etch process. In one embodiment, each of the pad cavities 189P may be formed with a respective concave sidewall having a uniform radius of curvature R. In one embodiment, the concave sidewall of each pad cavity 189P may have a uniform radius of curvature R throughout. The centers of curvature for each concave sidewall of a pad cavity 189P may be located at the bottom periphery of a respective opening in the etch mask layer 188. In other words, the loci of the centers of curvature for each concave sidewall of a pad cavity 189P may be the bottom periphery of a respective opening in the etch mask layer 188. In one embodiment, the radius of curvature R may be less than the thickness of the first silicon carbide nitride layer 186. In this case, the entirety of the concave surface of each pad cavity 189P may be formed within the first silicon carbide nitride layer 186.

Referring to FIG. 1E, an anisotropic etch process can be performed to etch the materials of the first bonding-level dielectric layer 180 while the etch mask layer 188 is present. The anisotropic etch process can etch portions of the first bonding-level dielectric layer 180 that are located within the areas of the openings in the etch mask layer 188. Via cavities 189V can be formed in a lower portion of the first bonding-level dielectric layer 180 by the anisotropic etch process. Each contiguous combination of a via cavity 189V and a pad cavity 189P constitutes an integrated pad-and-via cavity 189.

In one embodiment, the via cavities 189V may have straight sidewalls. In one embodiment, each straight sidewall may have a uniform taper angle with respective to a vertical direction in a range from 0.1 degree to 5 degrees, such as from 0.2 degree to 3 degrees. In one embodiment, each concave sidewall of a pad cavity 189P may have a respective bottom periphery that coincides with a top periphery of a respective underlying via cavity 189V. In one embodiment, the boundary between the via cavity 189V and the pad cavity 189P may be formed within or above the horizontal plane including the interface between the first silicate glass layer 184 and the first silicon carbide nitride layer 186.

In one embodiment, the ratio of the height of a pad cavity 189P to the height of an underlying via cavity 189V may be in a range from ¼ to 4, such as from ½ to 2, and/or from ⅔ to 3/2, although lesser and greater ratios may also be employed. In one embodiment, the centers of curvature of the concave sidewall of each pad cavity 189P may be located within a closed two-dimensional shape that is congruent with the top periphery of a respective underlying via cavity 189V, and may be located entirely within a horizontal plane including a top surface of the first bonding-level dielectric layer 180. As used herein, two shapes are congruent if the two shapes can be identical upon translation and/or rotation.

Referring to FIGS. 1F and 1G, the etch mask layer 188 can be removed selective to the materials of the first bonding-level dielectric layer 180. In one embodiment, the etch mask layer 188 may be removed by ashing or by performing a selective etch process, such as a wet etch process.

Referring to FIG. 1H, at least one metallic material can be deposited in the integrated pad-and-via cavities 189, and excess portions of the at least one metallic material can be removed from above the horizontal plane including the top surface of the first silicon carbide nitride layer 186 by performing a planarization process. In one embodiment, the at least one metallic material may comprise a combination of a conductive metallic barrier material and a metallic fill material. The conductive metallic barrier material may comprise a metallic nitride or carbide material, such as WN, TiN, TaN, MON, TiC, TaC, and/or WC, and may have thickness in a range from 5 nm to 50 nm, although lesser and greater thicknesses may also be employed. The conductive metallic barrier material may be deposited by physical vapor deposition or by chemical vapor deposition. The metallic fill material comprises a high-conductivity metal, such as W, Cu, Al, Mo, Co, Ru, alloys thereof, such as Cu—Al, etc. The metallic fill material may be deposited by physical vapor deposition, electroplating, electroless plating, and/or chemical vapor deposition. The planarization process that may be employed to remove excess portions of the at least one metallic material from above the horizontal plane including the top surface of the first silicon carbide nitride layer 186 may employ chemical mechanical polishing.

Each remaining portion of the at least one metallic material that fills a respective first integrated pad-and-via cavity 189 constitutes a first integrated metal bonding pad 190. In one embodiment, each of the first integrated metal bonding pads 190 comprises a combination of a first metallic barrier liner 190B (which is a patterned portion of the conductive metallic barrier material) and a first metallic fill material portion 190F (which is a patterned portion of the metallic fill material). In one embodiment, each of the first integrated metal bonding pads 190 comprises a respective metallic via portion 190V that is laterally surrounded by the first silicate glass layer 184 and a respective metallic pad portion 190P that is laterally surrounded by the first silicon carbide nitride layer 186.

In summary, an array of first integrated metal bonding pads 190 can be formed within the combination of the pad cavities 189P and the via cavities 189V. In one embodiment, each of the first integrated metal bonding pads 190 comprises a respective metallic via portion 190V that is formed within a respective one of the via cavities 189V, and a respective metallic pad portion 190P that is formed within a respective one of the pad cavities 189P. In one embodiment, the first integrated metal bonding pads 190 may have planar top surfaces within a horizontal plane including a top surface of the first bonding-level dielectric layer 180. In one embodiment, the ratio of the height of the respective metallic pad portion 190P to the height of the respective metallic via portion 190V may be in a range from ¼ to 4.

The array of first integrated metal bonding pads 190 may be embedded within the first bonding-level dielectric layer 180, and may be electrically connected to a respective one of the first metal interconnect structures 140. In one embodiment, each of the first integrated metal bonding pads 190 comprises a respective metallic via portion 190V that extends through a lower portion of the first bonding-level dielectric layer 180, and a respective metallic pad portion 190P having a convex sidewall that extends through an upper portion of the first bonding-level dielectric layer 180. In one embodiment, the convex sidewall of the respective metallic pad portion 190P has a uniform radius of curvature R throughout. In one embodiment, centers of curvature of the convex sidewall of the respective metallic pad portion 190P may be located within a closed two-dimensional shape that is congruent with the top periphery of the respective metallic via portion 190V and is located entirely within a horizontal plane including a top surface of the first bonding-level dielectric layer 180.

In one embodiment, the convex sidewall may have a bottom periphery that coincides with a top periphery of the respective metallic via portion 190V. In one embodiment, the first bonding-level dielectric layer 180 comprises a layer stack that includes a first silicate glass layer 184 and a first silicon carbide nitride layer 186 that overlies the first silicate glass layer 184, and a boundary between the respective metallic via portion 190V and the respective metallic pad portion 190P may be located entirely within the first silicon carbide nitride layer 186.

Referring to FIG. 1J, a second semiconductor die 200 is illustrated. The second semiconductor die 200 can be formed by performing a same set of processing steps as the first semiconductor die 100 described with reference to FIGS. 1A-1I.

Generally, a second semiconductor die 200 can be provided, which comprises second semiconductor devices 220 located on a second substrate 208, second metal interconnect structures 240 embedded in second dielectric material layers 230 and electrically connected to the second semiconductor devices 220, a second bonding-level dielectric layer 280 located on the second dielectric material layers 230, and an array of second metal bonding pads 290 embedded within the second bonding-level dielectric layer 280 and electrically connected to a respective one of the second metal interconnect structures 240.

The second bonding-level dielectric layer 280 comprises a second etch-stop dielectric layer 282, a second silicate glass layer 284, and a second silicon carbide nitride layer 286. The second etch-stop dielectric layer 282 comprises a dielectric material that can be employed as an etch-stop structure. For example, the second etch-stop dielectric layer 282 may comprise silicon nitride, silicon carbide, silicon carbide nitride, and/or a dielectric metal oxide. The thickness of the second etch-stop dielectric layer 282 may be in a range from 10 nm to 50 nm, although lesser and greater thicknesses may also be employed. The second silicate glass layer 284 comprises a silicate glass material such as undoped silicate glass or a doped silicate glass. The range of the thickness of the second silicate glass layer 284 may be the same as that of the range of the thickness of the first silicate glass layer 184. The second silicon carbide nitride layer 286 may have the same thickness range as the first silicon carbide nitride layer 186.

The array of second metal bonding pads 290 can be formed in the same manner employed to form the first integrated metal bonding pads 190. The pattern of the array of second metal bonding pads 290 as seen in a plan view may be a mirror image pattern of the pattern of the first integrated metal bonding pads 190. In one embodiment, each of the second metal bonding pads 290 may comprise a respective metallic via portion 290V that extends through a distal portion of the second bonding-level dielectric layer 280, and a respective metallic pad portion 290P having a convex sidewall that extends through a proximal portion of the second bonding-level dielectric layer 280. In one embodiment, the convex sidewalls of the metallic pad portions 290P of the second metal bonding pads 290 may have a uniform radius of curvature R′. In one embodiment, each of the second metal bonding pads 290 comprises a combination of a second metallic barrier liner 290B and a second metallic fill material portion 290F. In one embodiment, each of the second metal bonding pads 290 comprises a respective metallic via portion 290V that is laterally surrounded by a second silicate glass layer 284 and a respective metallic pad portion 290P that is laterally surrounded by a second silicon carbide nitride layer 286.

Referring to FIG. 1K, the second semiconductor die 200 can be bonded to the first semiconductor die 100 to form a first bonded assembly. In one embodiment, the second metal bonding pads 290 can be bonded to the first integrated metal bonding pad 190 by metal-to-metal bonding. As used herein, “metal-to-metal” bonding refers to a direct bonding between mating pairs of bonding pads. Thus, there is no intervening metallic material such as a solder material between mating pairs of bonding pads that are bonded to each other via metal-to-metal bonding. In one embodiment, the second metal bonding pads 290 can be bonded to the first integrated metal bonding pad 190 by copper-to-copper bonding, which is a metal-to-metal bonding between at least one pair of copper pads. In this case, the first metallic fill material portions 190F and the second metallic fill material portion 290F may consist essentially of copper or copper alloy. In one embodiment, a dielectric-to-dielectric bonding may also be performed between the second silicon carbide nitride layer 286 and the first silicon carbide nitride layer 186 in addition to the metal-to-metal bonding.

Referring to FIG. 1L, an alternative configuration of the first semiconductor die 100 is illustrated. In this configuration, the isotropic etch process that etches the material of the first silicon carbide nitride layer 186 may be selective to the material of the first silicate glass layer 184, and the duration of the isotropic etch process is selected such that the radius of curvature R of the pad cavities 189P (as formed at a processing step that corresponds to the processing step described with reference to FIG. 1D) is greater than the thickness of the first silicon carbide nitride layer 186. In this case, the pad cavities 189P may be formed with an annular planar bottom surface (i.e., a planar horizontal surface), which comprises a physically exposed surface of the first silicate glass layer 184.

Each first integrated metal bonding pad 190 is formed with a respective metallic pad portion 190P and a respective metallic via portion 190V. The respective metallic pad portion 190P comprises an annular planar bottom surface (i.e., planar horizontal surface) having an inner periphery that coincides with a top periphery of the respective metallic via portion 190V. In one embodiment, the outer periphery of the annular planar bottom surface of each metallic pad portion 190P coincides with a bottom periphery of the convex sidewall of the metallic pad portion 190P.

Referring to FIG. 1M, a second semiconductor die 200 may be provided as described with reference to FIG. 1J. Optionally, the second semiconductor die 200 may be formed in the alternative configuration described with reference to FIG. 1K. The second semiconductor die 200 can be bonded to the first semiconductor die 100, for example, by metal-to-metal bonding.

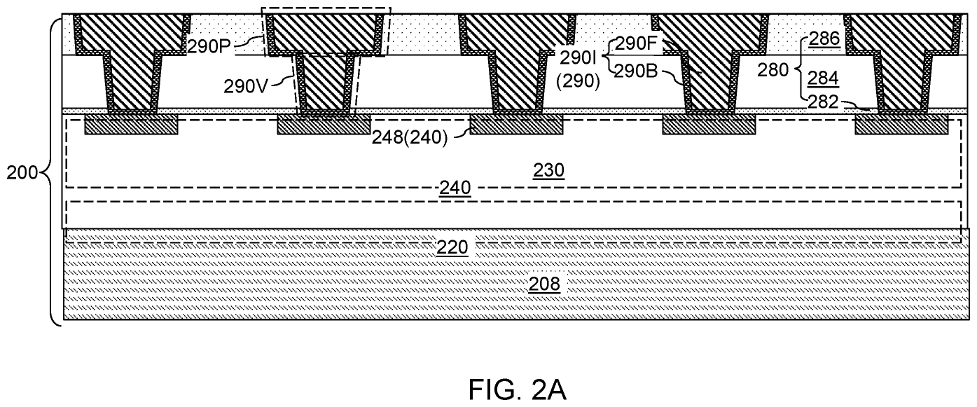

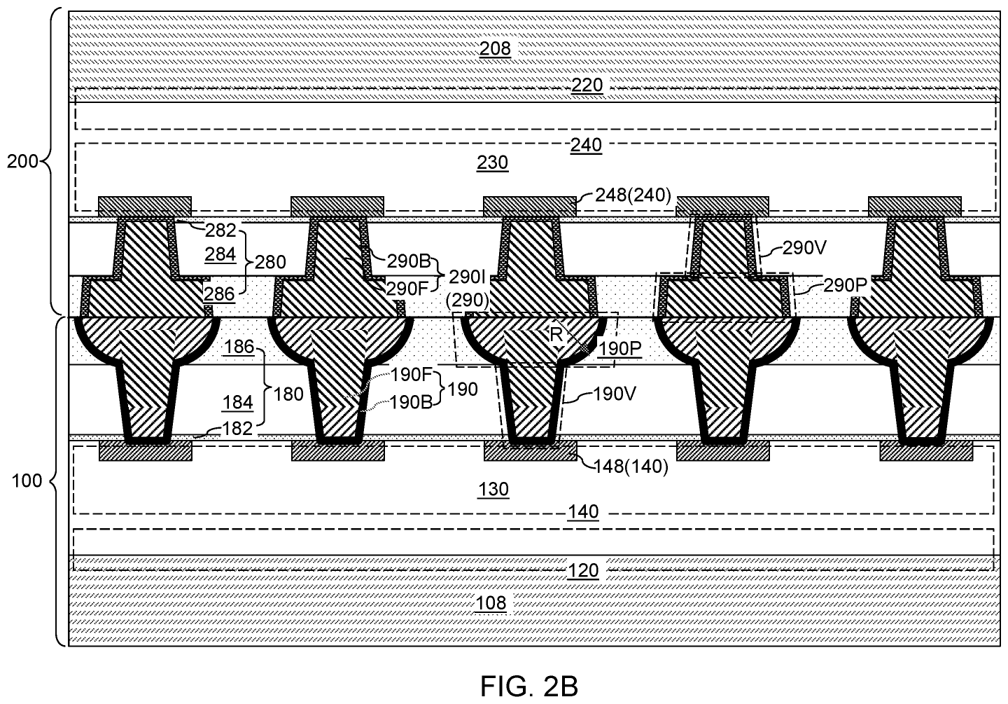

Referring to FIG. 2A, another configuration for the second semiconductor die 200 is illustrated. In this case, the metallic pad portions 290P of the second metal bonding pads 290 may be formed straight sidewalls. For example, the second metal bonding pads 290 may be formed employing a dual damascene method. In this embodiment, each of the second metal bonding pads 290 may comprise a respective metallic via portion 290V that extends through a distal portion of the second bonding-level dielectric layer 280, and a respective metallic pad portion 290P having straight sidewalls that extend through a proximal portion of the second bonding-level dielectric layer 280. In one embodiment, each of the second metal bonding pads 290 comprises a combination of a second metallic barrier liner 290B and a second metallic fill material portion 290F. In one embodiment, each of the second metal bonding pads 290 comprises a respective metallic via portion 290V that is laterally surrounded by a second silicate glass layer 284 and a respective metallic pad portion 290P that is laterally surrounded by a second silicon carbide nitride layer 286.

Referring to FIG. 2B, the second semiconductor die 200 described with reference to FIG. 2A may be bonded to the first semiconductor die 100 described with reference to FIG. 1I or to the first semiconductor die 100 described with reference to FIG. 1L, for example, by metal-to-metal bonding. A second bonded assembly is formed.

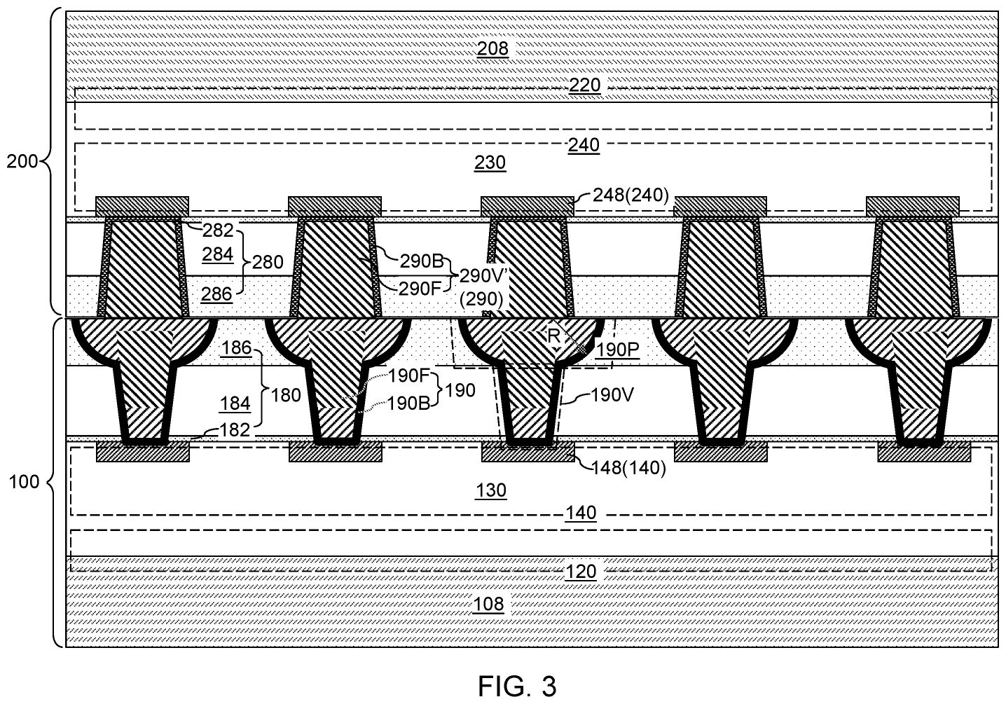

Referring to FIG. 3, a third bonded assembly of a first semiconductor die 100 and a second semiconductor die 200 is illustrated. The third bonded assembly may be derived from the first bonded assembly or the second bonded assembly described above by employing via metal bonding pads as second metal bonding pads 290. In this case, each second metal bonding pad 290 may consist of a metallic via portion 290V′, and does not include any metallic pad portion. Each metallic via portion 290V′ may comprise a combination of a second metallic barrier liner 290B (which is a patterned portion of a conductive metallic barrier material) and a second metallic fill material portion 290F (which is a patterned portion of a metallic fill material). The second metal bonding pads 290 may be bonded to the first integrated metal bonding pads 190 by metal-to-metal bonding.

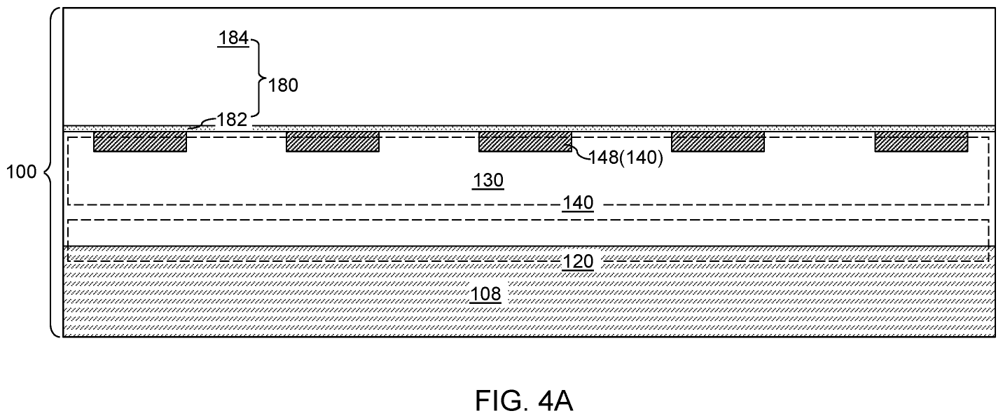

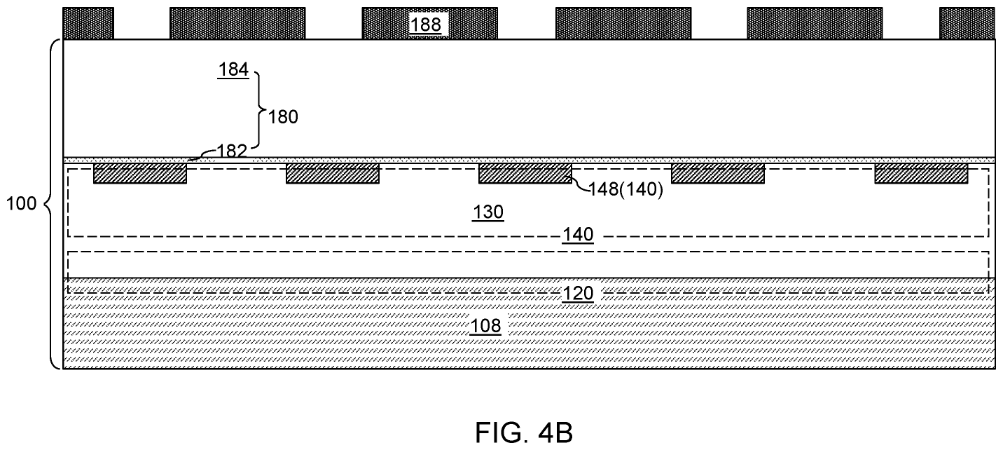

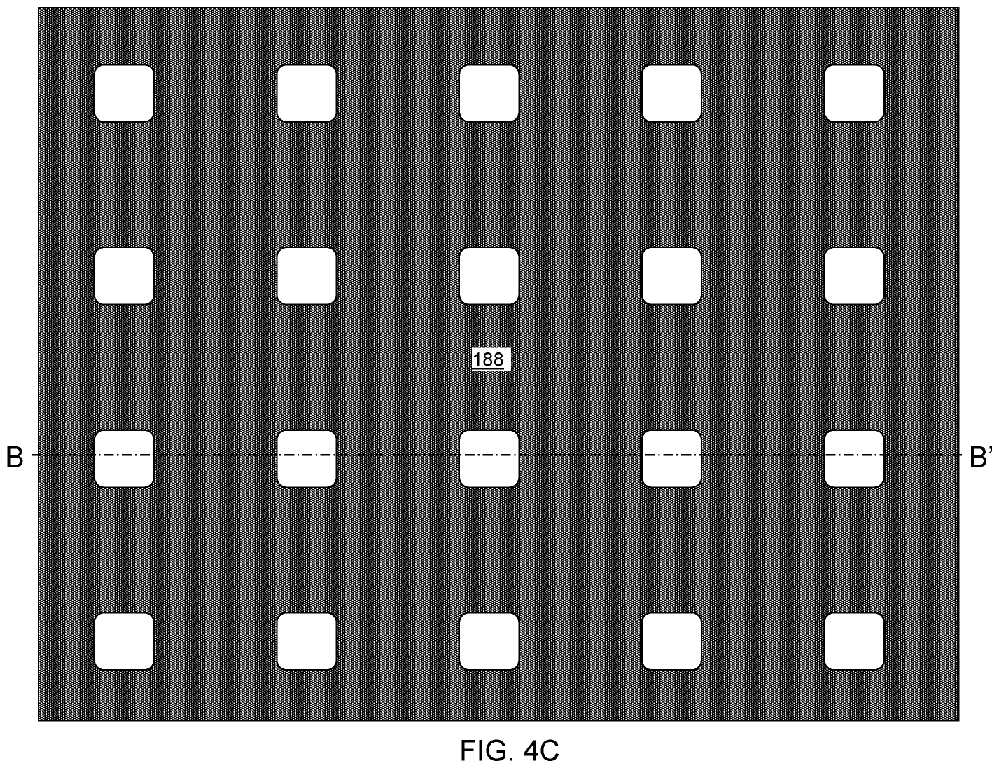

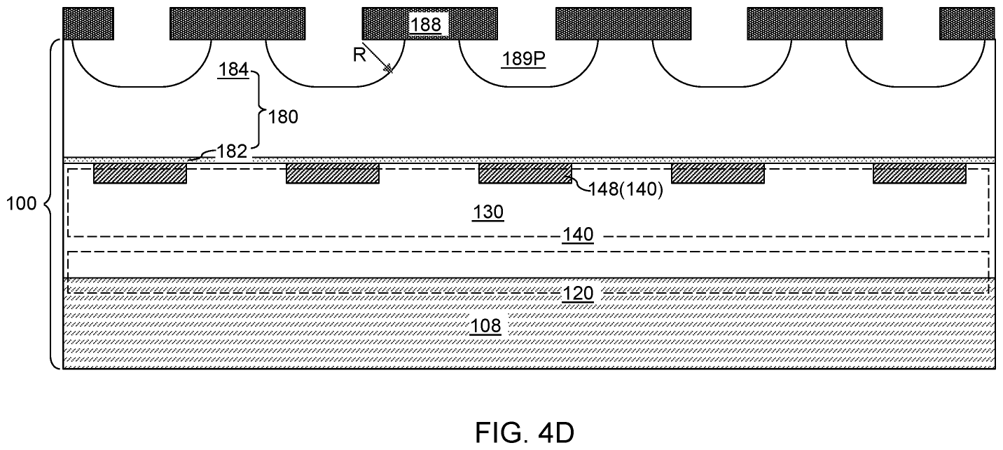

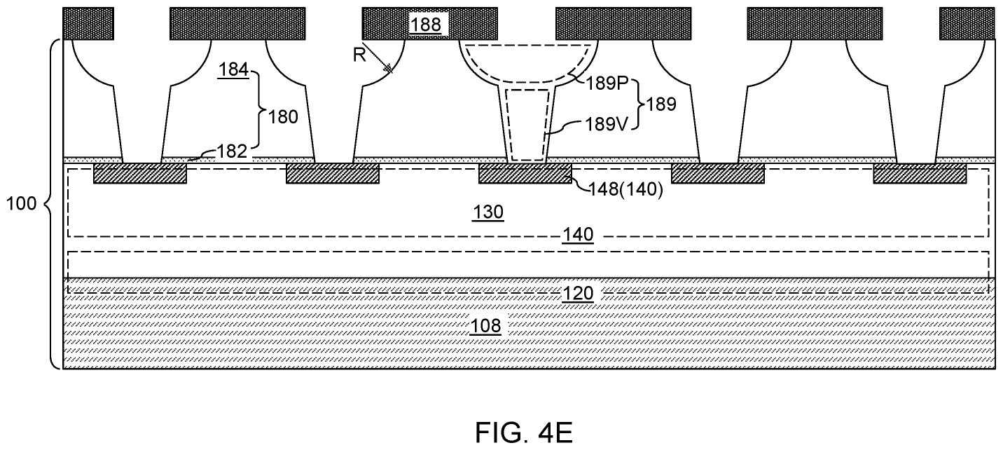

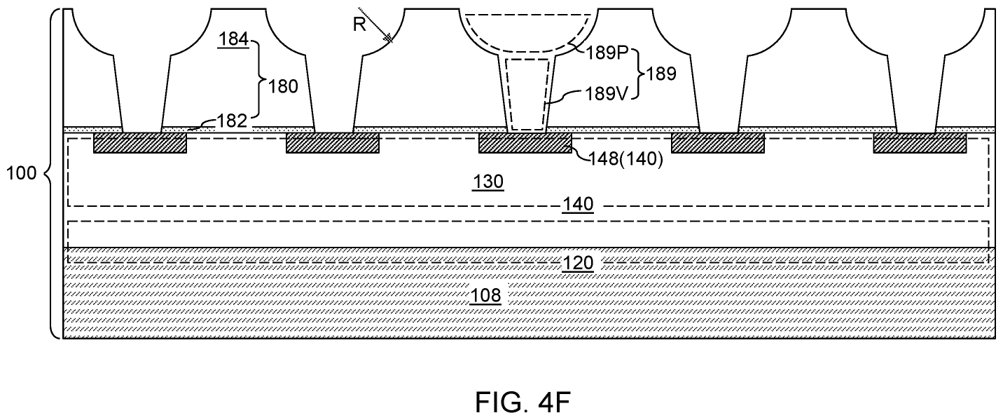

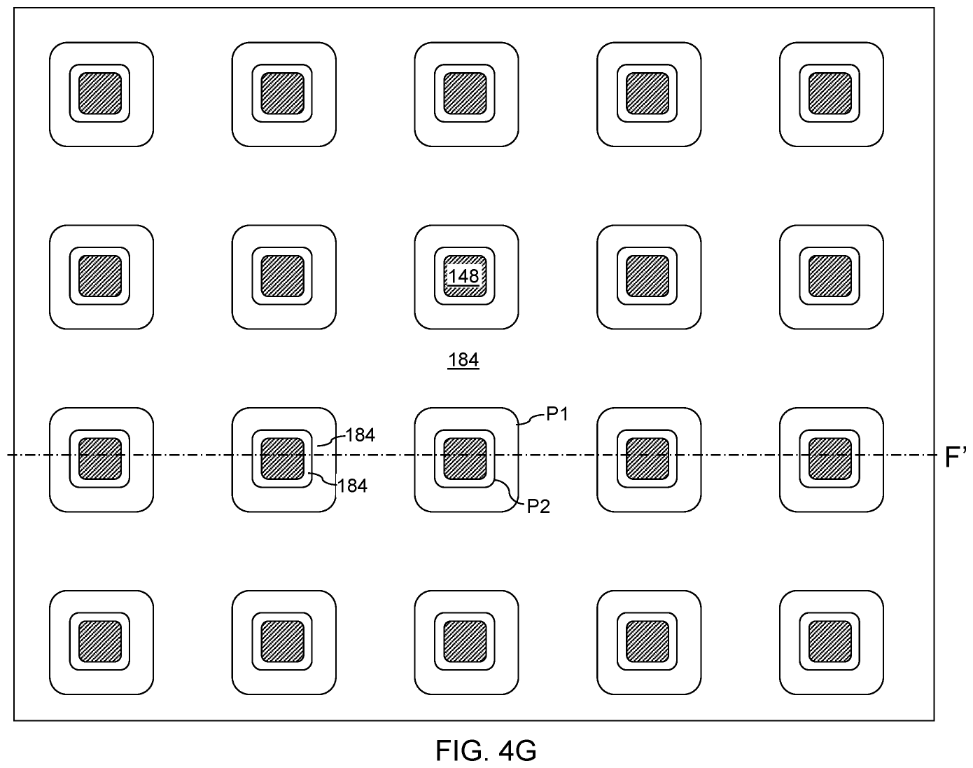

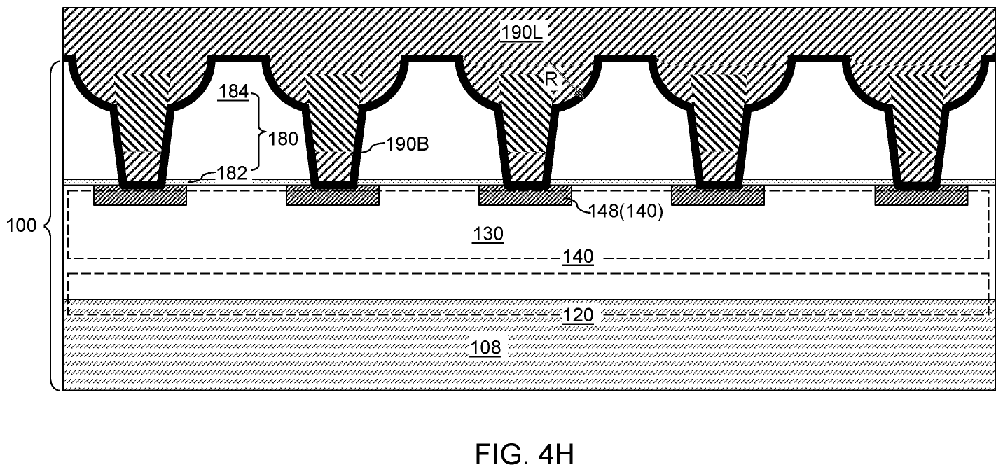

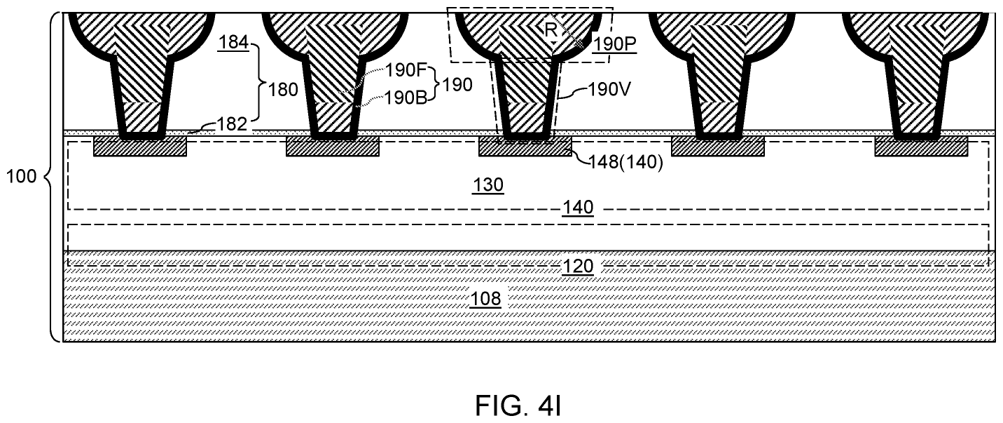

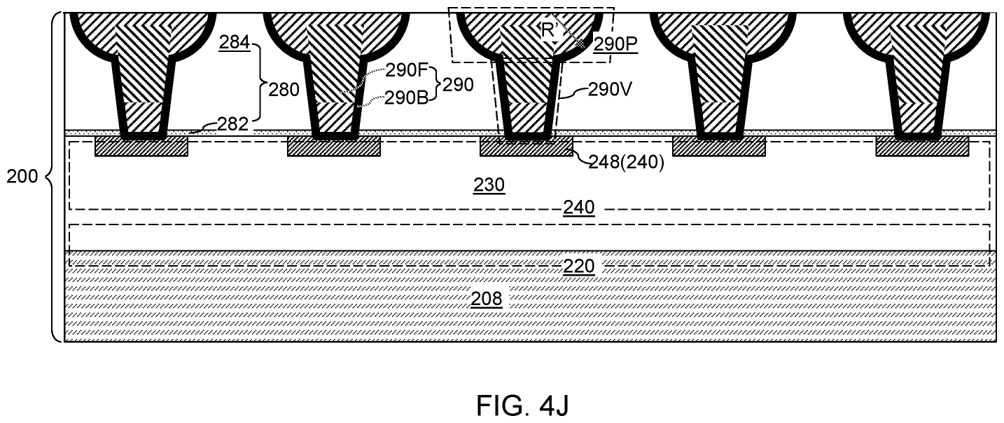

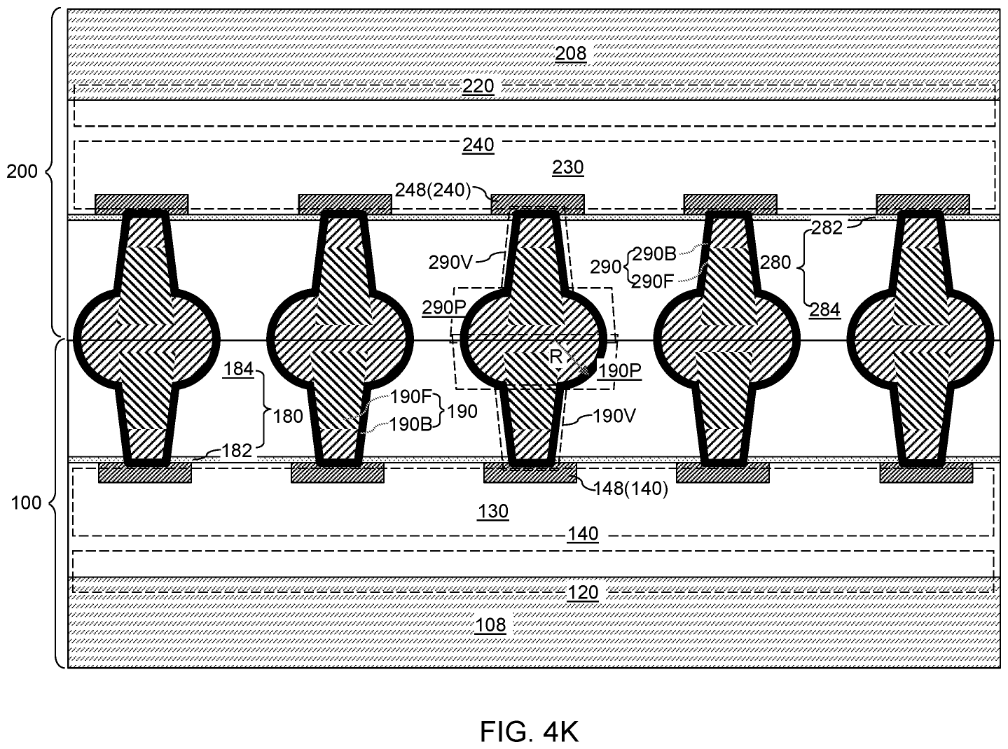

FIGS. 4A, 4B, 4D, 4E, 4F, 4H, and 4I are sequential vertical cross-sectional views of a first exemplary structure during formation of a fourth bonded assembly of a first semiconductor die 100 and a second semiconductor die 200 according to an embodiment of the present disclosure. FIG. 4C is a top-down view of the first exemplary structure of FIG. 4B. The vertical plane B-B′ in FIG. 4C is the cut plane of the vertical cross-sectional view of FIG. 4B. FIG. 4G is a top-down view of the first exemplary structure of FIG. 4F. The vertical plane F-F′ in FIG. 4G is the cut plane of the vertical cross-sectional view of FIG. 4F. FIG. 4J is a vertical cross-sectional view of a second semiconductor die 200. FIG. 4K is a vertical cross-sectional view of the fourth bonded assembly of the first semiconductor die 100 and the second semiconductor die 200.

Referring collectively to FIGS. 4A-4K, the fourth bonded assembly can be derived from the first bonded assembly described with reference to FIGS. 1A-1K by employing a first bonding-level dielectric layer 180 which lacks the silicon carbide nitride layer 186. In this embodiment, the first bonding-level dielectric layer 180 consists of only the first silicate glass layer 184 in the first semiconductor die 100. Optionally, the second bonding-level dielectric layer 280 consists of only the second silicate glass layer 284 in the second semiconductor die 200. The first silicate glass layer 184 may have a top surface within a horizontal plane including top surfaces of the first integrated metal bonding pads 190. The second silicate glass layer 284 may have a top surface within a horizontal plane including top surfaces of the second metal bonding pads 290. Upon bonding of the first integrated metal bonding pads 190 with the second metal bonding pads 290, the first silicate glass layer 180 may be bonded to the second silicate glass layer 280 by dielectric-to-dielectric bonding (such as silicon oxide-to-silicon oxide bonding).

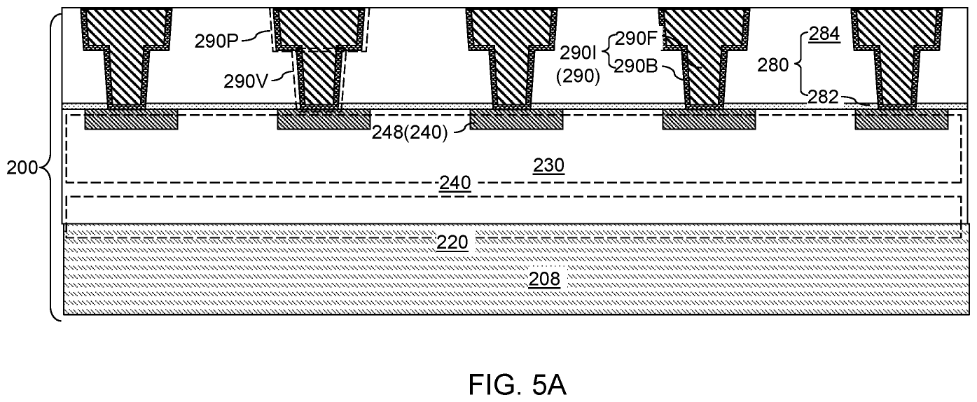

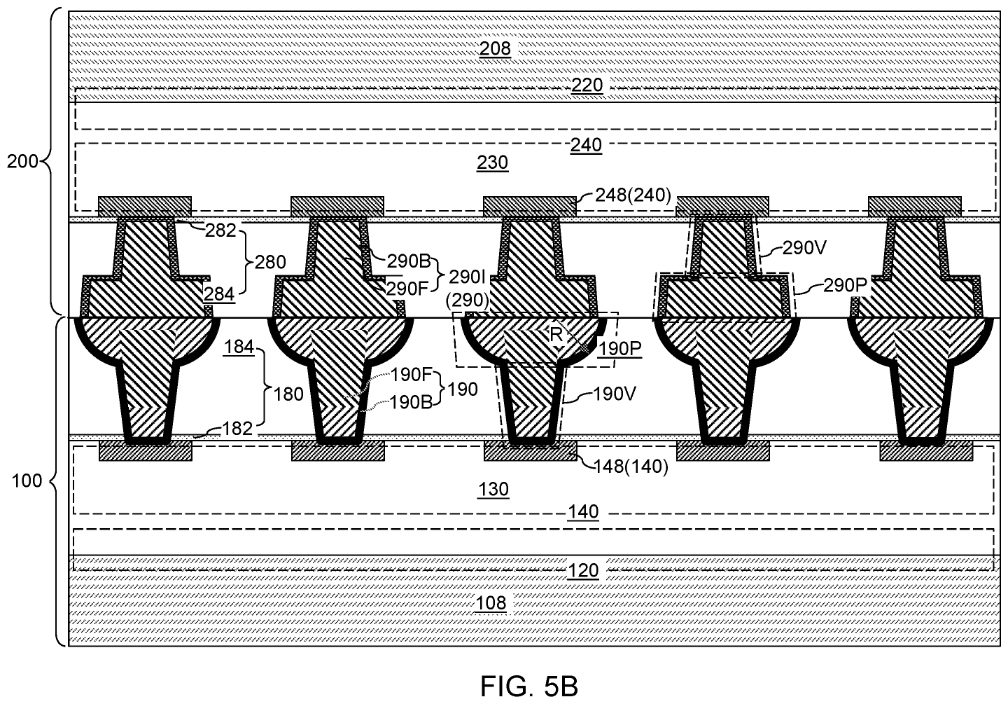

Referring to FIG. 5A, a second semiconductor die 200 for forming a fifth bonded assembly can be derived from the second semiconductor die 200 illustrated in FIG. 2A by employing a second bonding-level dielectric layer 280 consisting of a second silicate glass layer 284 in the second semiconductor die 200.

Referring to FIG. 5B, a fifth bonded assembly of a first semiconductor die 100 and the second semiconductor die 200 of FIG. 5A is shown. In the fifth bonded assembly, the first semiconductor die 100 illustrated in FIG. 4I can be bonded with the second semiconductor die 200 illustrated in FIG. 5A. Upon bonding of the first integrated metal bonding pads 190 with the second metal bonding pads 290, the first silicate glass layer 180 may be bonded to the second silicate glass layer 280 by dielectric-to-dielectric bonding (such as silicon oxide-to-silicon oxide bonding).

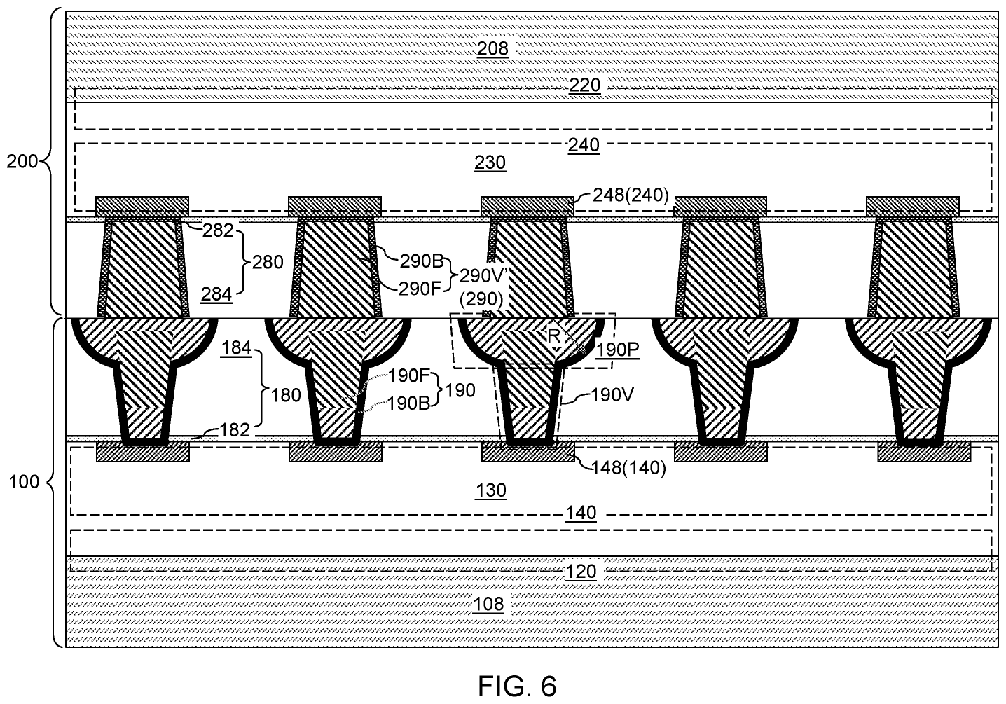

Referring to FIG. 6, a sixth bonded assembly of a first semiconductor die 100 and a second semiconductor die 200 is illustrated. The sixth bonded assembly may be derived from the fourth bonded assembly or the fifth bonded assembly described above by employing via metal bonding pads as second metal bonding pads 290. In this case, each second metal bonding pad 290 may consist of a metallic via portion 290V′, and does not include any metallic pad portion. Each metallic via portion 290V′ may comprise a combination of a second metallic barrier liner 290B (which is a patterned portion of a conductive metallic barrier material) and a second metallic fill material portion 290F (which is a patterned portion of a metallic fill material). The second metal bonding pads 290 may be bonded to the first integrated metal bonding pads 190 by metal-to-metal bonding.

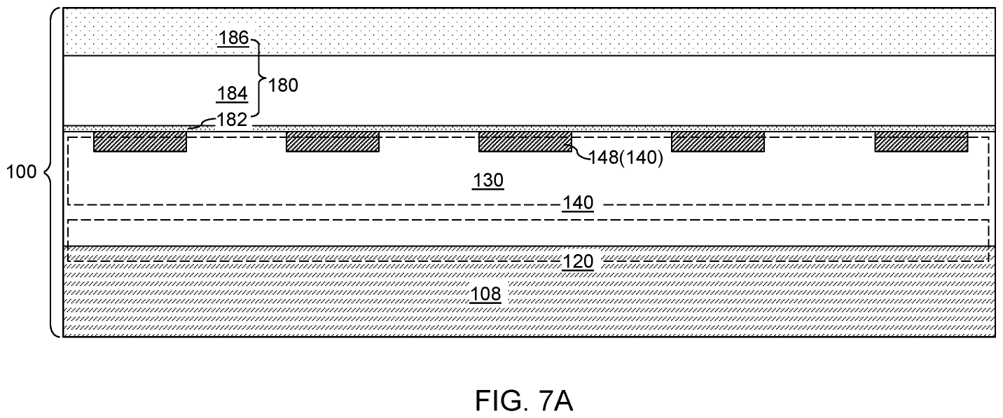

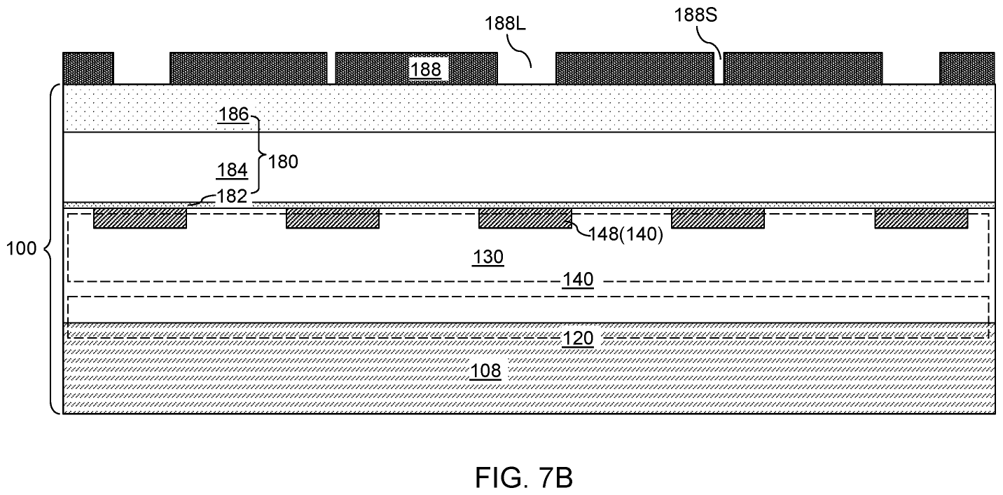

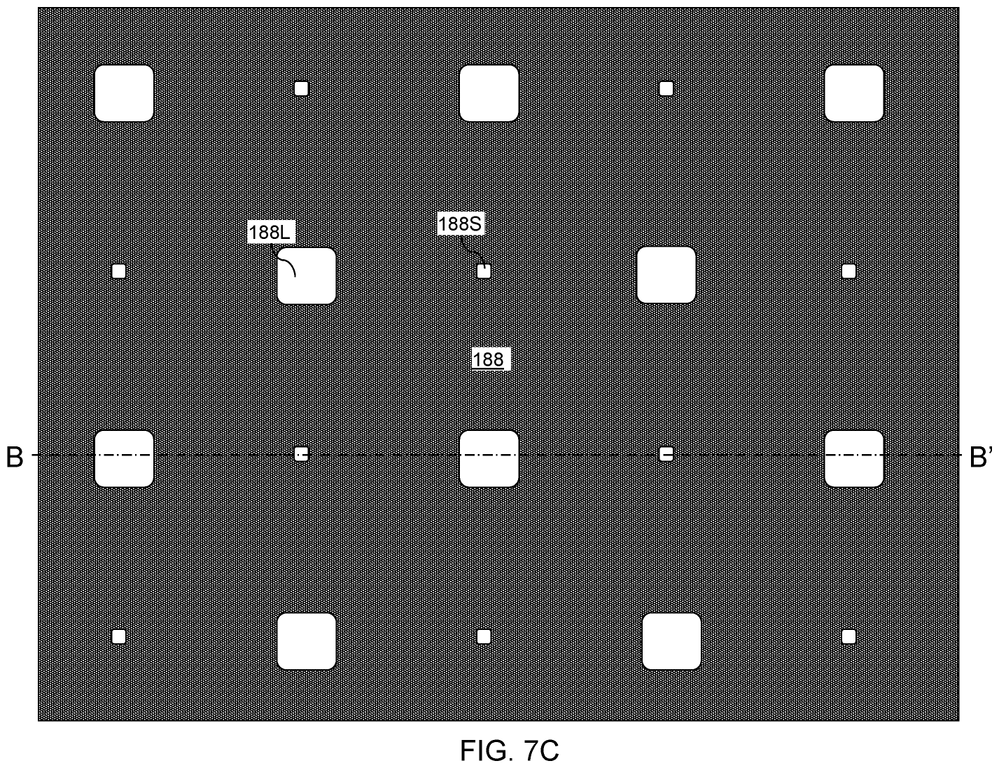

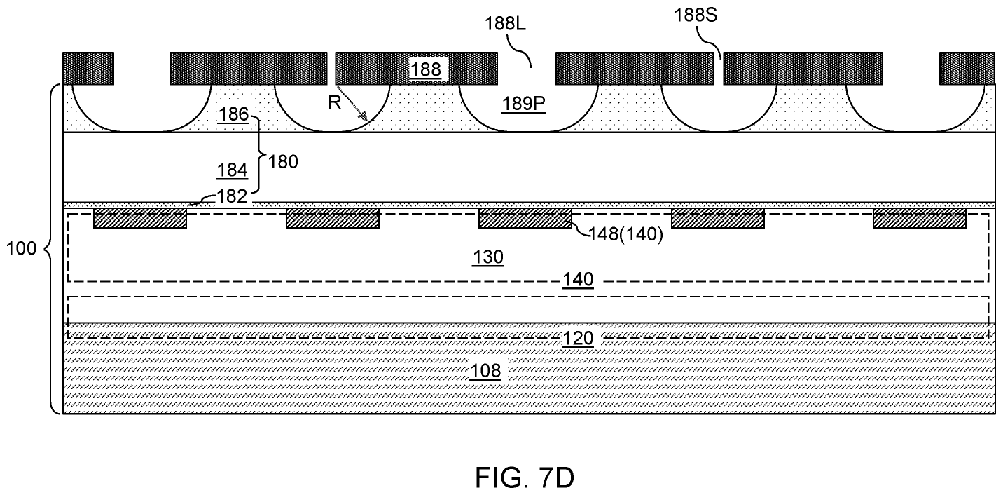

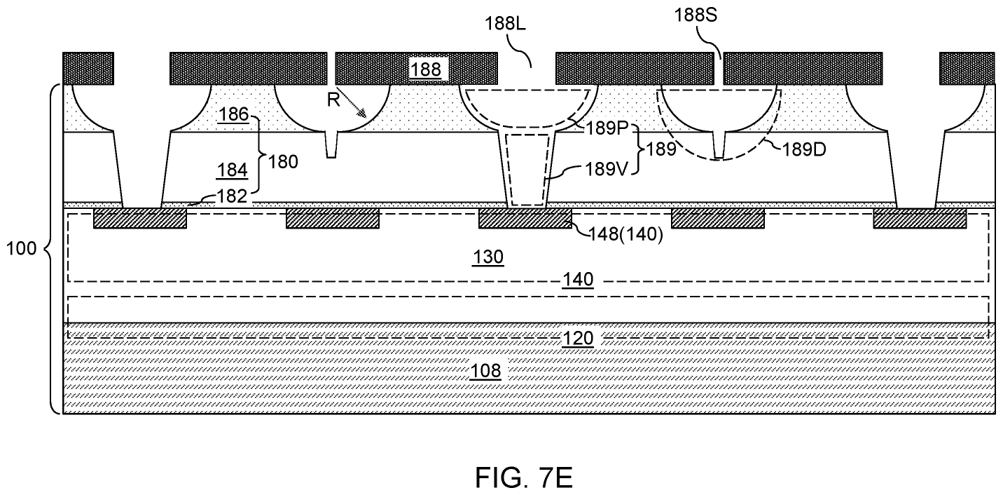

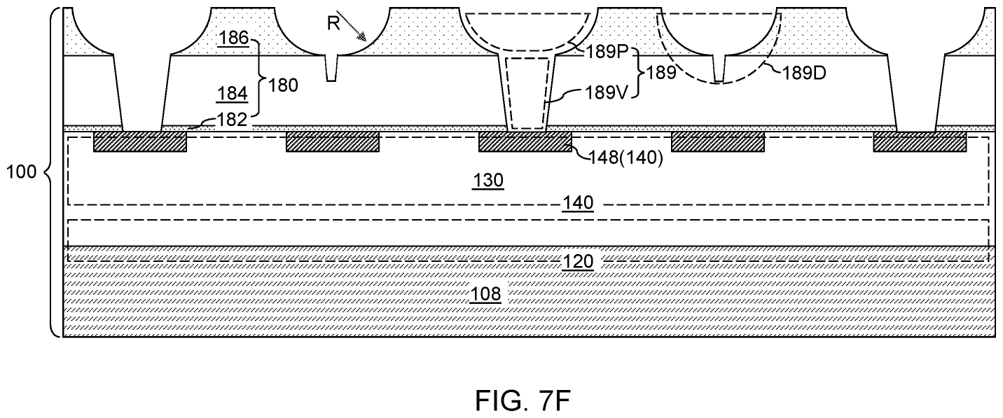

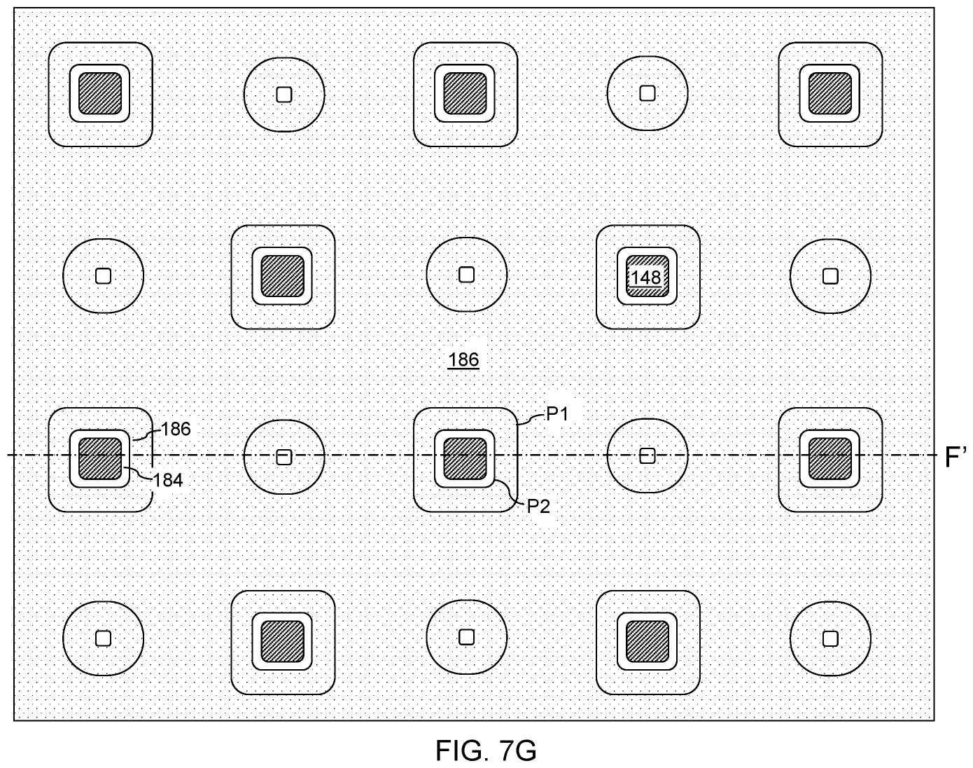

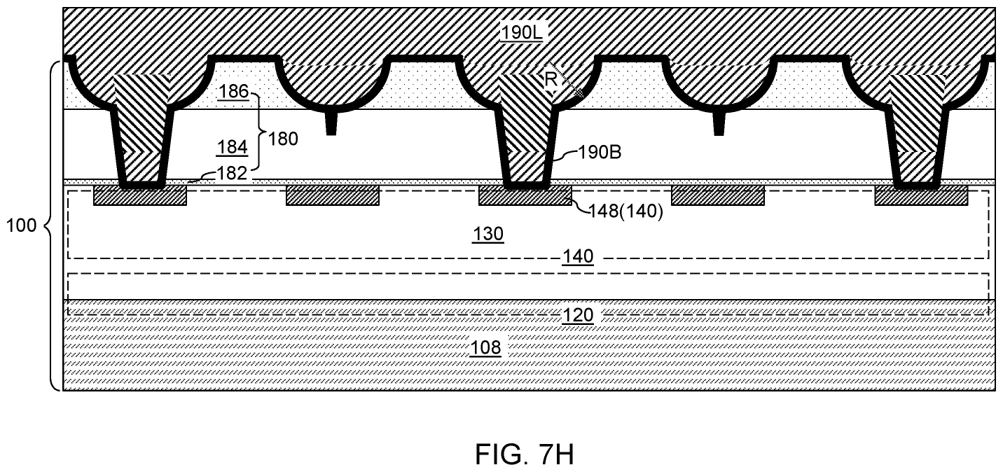

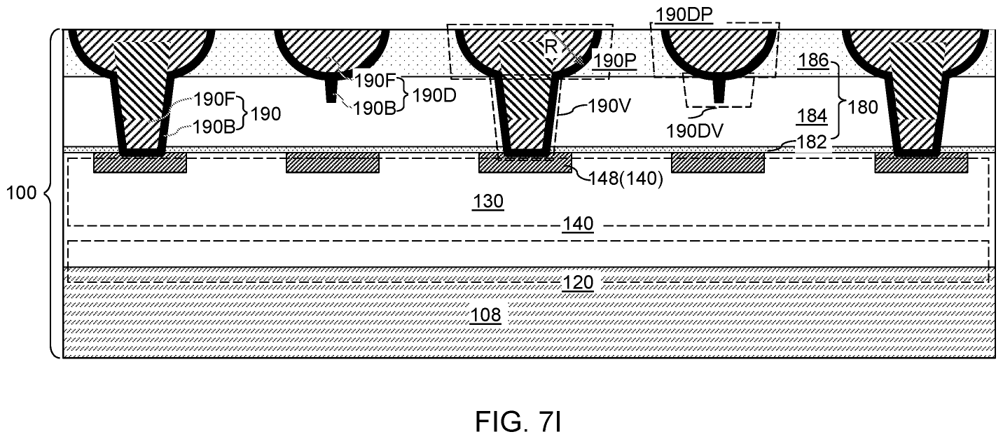

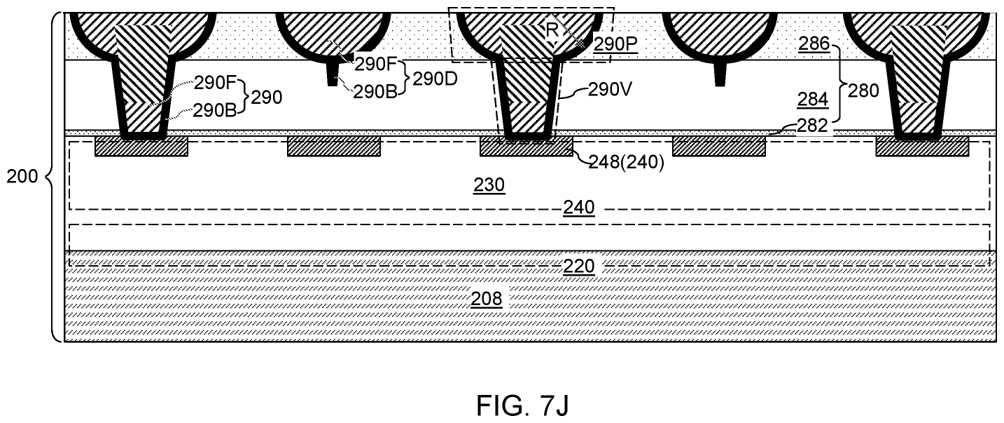

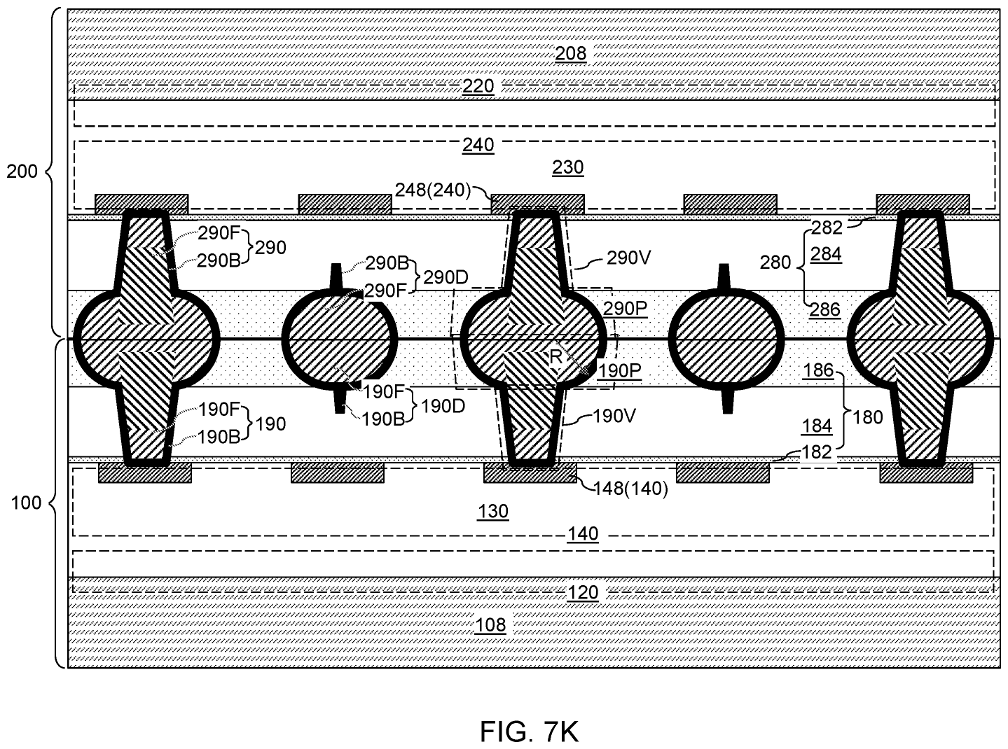

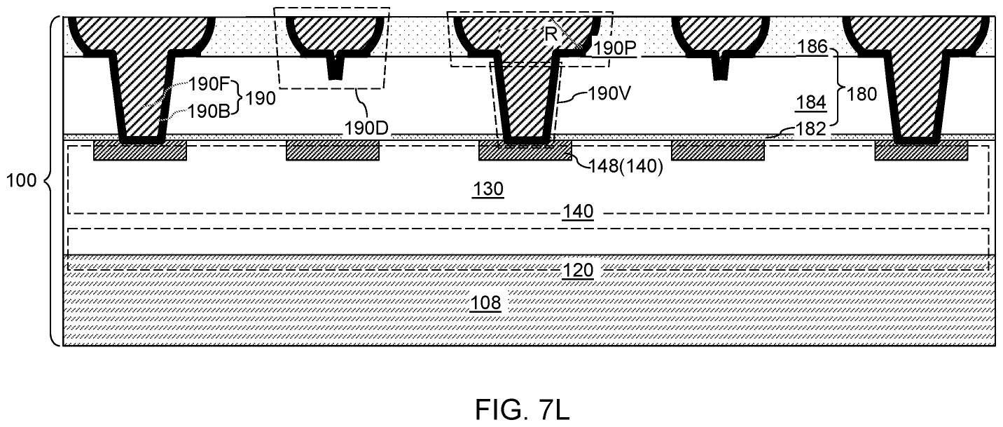

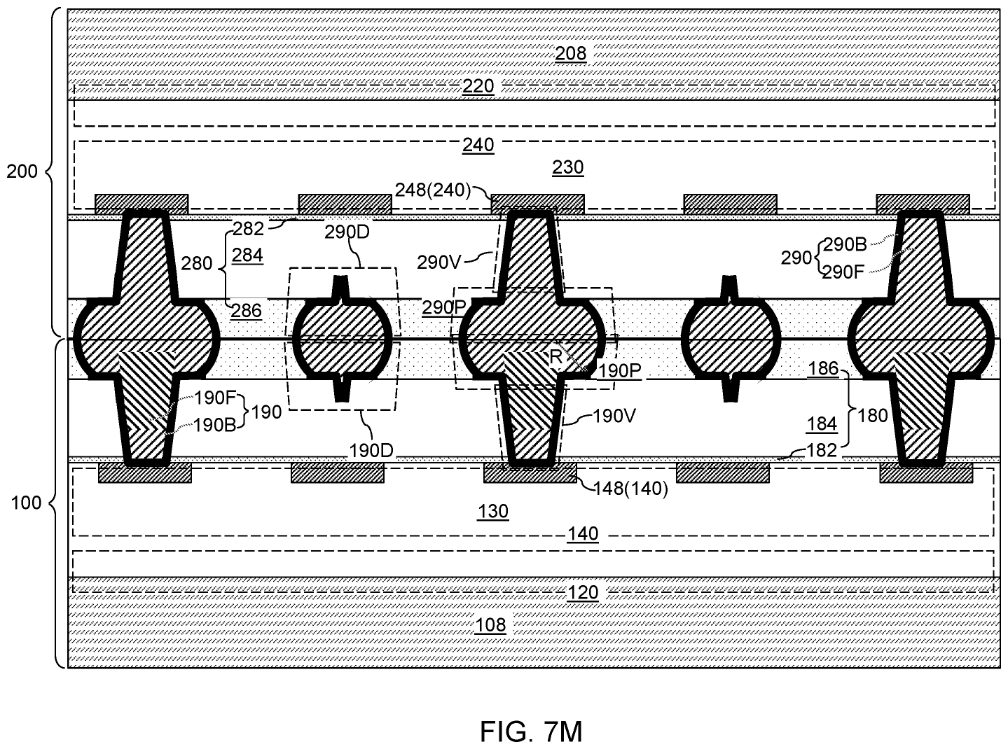

Referring to FIG. 7A, a first semiconductor die 100 for forming a seventh bonded assembly is illustrated. The first semiconductor die 100 in FIG. 7A may be the same as the first semiconductor die illustrated in FIG. 1A.

Referring to FIGS. 7B and 7C, an etch mask layer 188 can be formed over the first silicon carbide nitride layer 186. The etch mask layer 188 may have the same material composition and the same thickness range as the etch mask layer 188 illustrated in FIGS. 1A and 1B.

The etch mask layer 188 can be patterned to form an array of discrete openings therethrough. For example, a photoresist layer (not shown) can be applied over the etch mask layer 188, and can be lithographically patterned to form openings therein. An anisotropic etch process can be performed to transfer the pattern of the openings in the photoresist layer through the etch mask layer 188. In one embodiment, the pattern of the discrete openings in the etch mask layer 188 may comprise a first pattern having an array of larger openings 188L, and a second pattern having an array of smaller openings 188S. The larger openings in the first pattern may have a respective lateral dimension that is about the same of a lateral dimension of a metallic via portion of a first integrated metal bonding pad to be subsequently formed. The smaller openings in the second pattern may have a respective lateral dimension that is sufficiently small to induce formation of shallower via openings during a subsequent anisotropic etch process than via openings to be subsequently formed underneath the first pattern.

In an illustrative example, the first pattern may have an array of first openings each having a first lateral dimension (such as a diameter of a circular shape or a diagonal of a rectangle or a rounded rectangle). The first lateral dimension may be in a range from 100 nm to 400 nm, such as from 120 nm to 300 nm, although lesser and greater first lateral dimensions may also be employed. The second pattern may have an array of second openings each having a second lateral dimension (which may be a diameter of a circular shape or a diagonal of a rectangle or a rounded rectangle). The second lateral dimension may be in a range from 10 nm to 100 nm, such as from 20 nm to 50 nm, although lesser and greater second lateral dimensions may also be employed. Generally, the ratio of the second lateral dimension to the first lateral dimension is selected such that an anisotropic etch process that transfers the combination of the first pattern and the second pattern into the first bonding-level dielectric layer 180 forms via cavities that do not extend through the first bonding-level dielectric layer 180 underneath the second pattern while forming via cavities that extent through the first bonding-level dielectric layer 180 underneath the first pattern. For example, the ratio of the second lateral dimension to the first lateral dimension may be in a range from 0.05 to 0.5, such as from 0.1 to 0.3, although lesser and greater ratios may also be employed.

In one embodiment, the array of first openings 188L and the array of second openings 188S may be interlaced with each other as two checkerboard patterns that are laterally offset from each other by one half of the periodicity of each pattern along each pattern repetition direction. Alternatively, the first pattern and the second pattern may be different from each other. The total number of the first openings in the first pattern may optionally be about the same as the total number of second openings in the second pattern. The ratio of the total number of the second openings 188S (i.e., smaller openings) in the second pattern to the total number of the first openings 188L (i.e., larger openings) in the first pattern may be in a range from 0.1 to 10, and/or from ⅓ to 3, and/or from ⅔ to 3/2, although lesser and greater ratios may also be employed. In one embodiment each opening in the etch mask layer 188 may be formed entirely within the area of a respective underlying first topmost metal interconnect structure 148. The photoresist layer may be removed, for example, by ashing.

Referring to FIG. 7D, an isotropic etch process can be performed to isotropically etch the material of the first silicon carbide nitride layer 186 selective to the material of the etch mask layer 188. The anisotropic etch process may be the same as the anisotropic etch process described with reference to FIG. 1D.

Pad cavities 189P are formed in an upper portion of the first bonding-level dielectric layer 180 underneath the discrete openings in the etch mask layer 188 by performing the isotropic etch process. Generally, the openings 188L and 188S in the etch mask layer 188 are large enough to allow free movement of an isotropic etchant in a fluid phase (i.e., in a liquid phase or in a gas phase). Thus, the etch rate of the isotropic etch process is substantially independent of the size of the openings in the etch mask layer 188. In one embodiment, each of the pad cavities 189P may be formed with a respective concave sidewall having a uniform radius of curvature R. In one embodiment, the concave sidewall of each pad cavity 189P may have a uniform radius of curvature R throughout. The centers of curvature for each concave sidewall of a pad cavity 189P may be located at the bottom periphery of a respective opening in the etch mask layer 188. In other words, the loci of the centers of curvature for each concave sidewall of a pad cavity 189P may be the bottom periphery of a respective opening in the etch mask layer 188. In one embodiment, the radius of curvature R may be less than the thickness of the first silicon carbide nitride layer 186. In this case, the entirety of the concave surface of each pad cavity 189P may be formed within the first silicon carbide nitride layer 186. The difference between the lateral dimension of each pad cavity 189P underneath the first openings (i.e., the large openings) in the etch mask layer 188 and the lateral dimension of each pad cavity 189P underneath the second openings (i.e., the smaller openings) in the etch mask layer 188 may be the same as the difference between the lateral dimension of each first opening in the etch mask layer 188 and the lateral dimension of each second opening in the etch mask layer 188.

Referring to FIG. 7E, an anisotropic etch process can be performed to etch the materials of the first bonding-level dielectric layer 180 while the etch mask layer 188 is present. The anisotropic etch process can etch portions of the first bonding-level dielectric layer 180 that are located within the areas of the openings 188L and 188S in the etch mask layer 188. Via cavities 189V can be formed in a lower portion of the first bonding-level dielectric layer 180 by the anisotropic etch process. The etch rate of the anisotropic etch process is dependent on the size of the openings 188L and 188S in the etch mask layer 188. The duration of the anisotropic etch process is selected such that each via cavity 189V that is formed underneath a respective first opening 188L (i.e., a larger opening) in the etch mask layer 188 vertically extends through the entire first silicate glass layer 184 so that a top surface of a topmost metal interconnect structure 148 is exposed underneath each via cavity 189V underlying a respective first opening 188L. Further, the duration of the anisotropic etch process is selected such that each via cavity that is formed underneath a respective second opening 188S (i.e., a smaller opening) in the etch mask layer 188 does not vertically extend through the entire first silicate glass layer 184, such that the bottom of the via cavity is located above the bottom surface first silicate glass layer 184 and the top surface of a topmost metal interconnect structure 148 is not exposed underneath each via cavity underlying the second opening 188S. Each contiguous combination of a via cavity 189V and a pad cavity 189P underlying a first opening 188L in the etch mask layer 188 constitutes an integrated pad-and-via cavity 189. Each contiguous combination of a via cavity and a pad cavity 189P underlying a second opening 188S in the etch mask layer 188 constitutes a dummy cavity 189D, which may be an integrated pad-and-via cavity.

Referring to FIGS. 7F and 7G, the etch mask layer 188 can be removed selective to the materials of the first bonding-level dielectric layer 180. In one embodiment, the etch mask layer 188 may be removed by ashing or by performing a selective etch process, such as a wet etch process.

Referring to FIGS. 7H and 7I, at least one metallic material can be deposited in the integrated pad-and-via cavities 189, and excess portions of the at least one metallic material can be removed from above the horizontal plane including the top surface of the first silicon carbide nitride layer 186 by performing a planarization process, as discussed above with respect to FIGS. 1H and 1I. Each remaining portion of the at least one metallic material that fills a respective first integrated pad-and-via cavity 189 constitutes a first integrated metal bonding pad 190. Each remaining portion of the at least one metallic material that fills a respective dummy cavity 189D constitutes a first dummy bonding pad 190D.

In one embodiment, each of the first integrated metal bonding pads 190 comprises a combination of a first metallic barrier liner 190B (which is a patterned portion of the conductive metallic barrier material) and a first metallic fill material portion 190F (which is a patterned portion of the metallic fill material). In one embodiment, each of the first dummy bonding pads 190D comprises a combination of a first metallic barrier liner 190B (which is a patterned portion of the conductive metallic barrier material) and a first metallic fill material portion 190F (which is a patterned portion of the metallic fill material). In one embodiment, each of the first integrated metal bonding pads 190 comprises a respective metallic via portion 190V that is laterally surrounded by the first silicate glass layer 184 and a respective metallic pad portion 190P that is laterally surrounded by the first silicon carbide nitride layer 186. The metallic via portion 190V electrically contacts the underlying topmost metal interconnect structures 148. In one embodiment, each of the first dummy bonding pads 190D comprises a respective metallic dummy via portion 190DV that is not in electrical contact with the underlying topmost metal interconnect structures 148, and that is laterally surrounded by the first silicate glass layer 184, and a respective metallic dummy pad portion 190DP that is laterally surrounded by the first silicon carbide nitride layer 186.

In summary, an array of first integrated metal bonding pads 190 can be formed within the combination of the pad cavities 189P and the via cavities 189V, and an array of first dummy bonding pads 190D can be formed within the first dummy cavities 189D. In one embodiment, the first integrated metal bonding pads 190 and the first dummy bonding pads 190D may have planar top surfaces within a horizontal plane including a top surface of the first bonding-level dielectric layer 180.

Referring to FIG. 7J, a second semiconductor die 200 is illustrated. The second semiconductor die 200 can be formed by performing a same set of processing steps as the first semiconductor die 100 described with reference to FIGS. 7A-7I.

The second semiconductor die 200 comprises second semiconductor devices 220 located on a second substrate 208, second metal interconnect structures 240 embedded in second dielectric material layers 230 and electrically connected to the second semiconductor devices 220, a second bonding-level dielectric layer 280 located on the second dielectric material layers 230, an array of second metal bonding pads 290 embedded within the second bonding-level dielectric layer 280 and electrically connected to a respective one of the second metal interconnect structures 240, and an array of second dummy bonding pads 290D embedded within the second bonding-level dielectric layer 280 and electrically isolated from the second metal interconnect structures 240.

Referring to FIG. 7K, the second semiconductor die 200 can be bonded to the first semiconductor die 100 to form a seventh bonded assembly. In one embodiment, the second metal bonding pads 290 can be bonded to the first integrated metal bonding pad 190 by metal-to-metal bonding. In one embodiment, the second dummy bonding pads 290D can be bonded to the first dummy bonding pad 190D by metal-to-metal bonding. In one embodiment, the second metal bonding pads 290 can be bonded to the first integrated metal bonding pad 190 by copper-to-copper bonding, which is a metal-to-metal bonding between at least one pair of copper pads. In this case, the first metallic fill material portions 190F and the second metallic fill material portion 290F may consist essentially of copper or copper alloy. Likewise, the second dummy bonding pads 290D can be bonded to the first dummy bonding pad 190D by copper-to-copper bonding. In one embodiment, a dielectric-to-dielectric bonding may also be performed between the second silicon carbide nitride layer 286 and the first silicon carbide nitride layer 186 in addition to the metal-to-metal bonding. The addition of the dummy bonding pads 190D and 290D enhance the bonding strength between the first and the second semiconductor die.

Referring to FIG. 7L, an alternative configuration of the first semiconductor die 100 is illustrated. In this configuration, the isotropic etch process that etches the material of the first silicon carbide nitride layer 186 may be selective to the material of the first silicate glass layer 184, and the duration of the isotropic etch process is selected such that the radius of curvature R of the pad cavities 189P (as formed at a processing step that corresponds to the processing step described with reference to FIG. 7D) is greater than the thickness of the first silicon carbide nitride layer 186. In this case, the pad cavities 189P may be formed with an annular planar bottom surface (i.e., a planar horizontal surface), which comprises a physically exposed surface of the first silicate glass layer 184.

Each first integrated metal bonding pad 190 is formed with a respective metallic pad portion 190P and a respective metallic via portion 190V. The respective metallic pad portion 190P comprises an annular planar bottom surface (i.e., planar horizontal surface) having an inner periphery that coincides with a top periphery of the respective metallic via portion 190V. In one embodiment, the outer periphery of the annular planar bottom surface of each metallic pad portion 190P coincides with a bottom periphery of the convex sidewall of the metallic pad portion 190P. Each first dummy bonding pad 190D is formed with a respective metallic dummy pad portion 190P and a respective metallic dummy via portion that is shorter than the thickness of the first silicate glass layer 184.

Referring to FIG. 7M, a second semiconductor die 200 may be provided as described with reference to FIG. 7J. Optionally, the second semiconductor die 200 may be formed in the alternative configuration described with reference to FIG. 7K. The second semiconductor die 200 can be bonded to the first semiconductor die 100, for example, by metal-to-metal bonding.

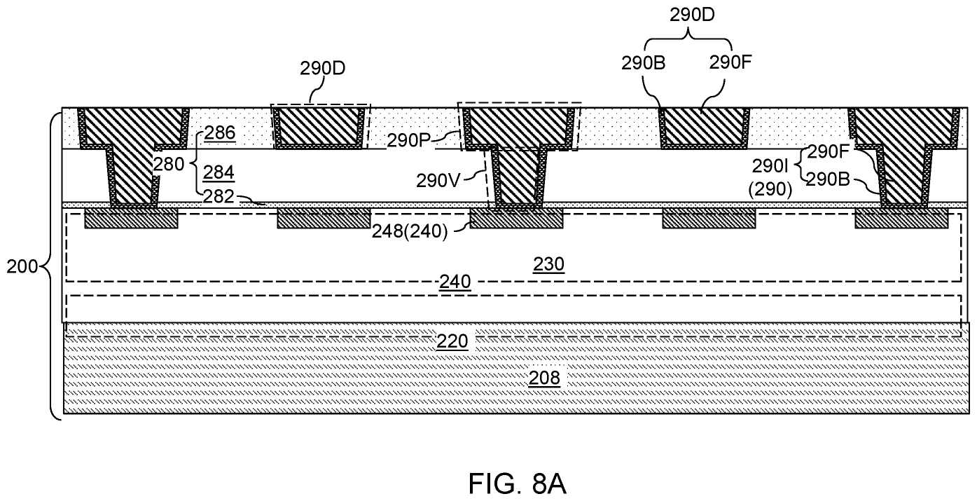

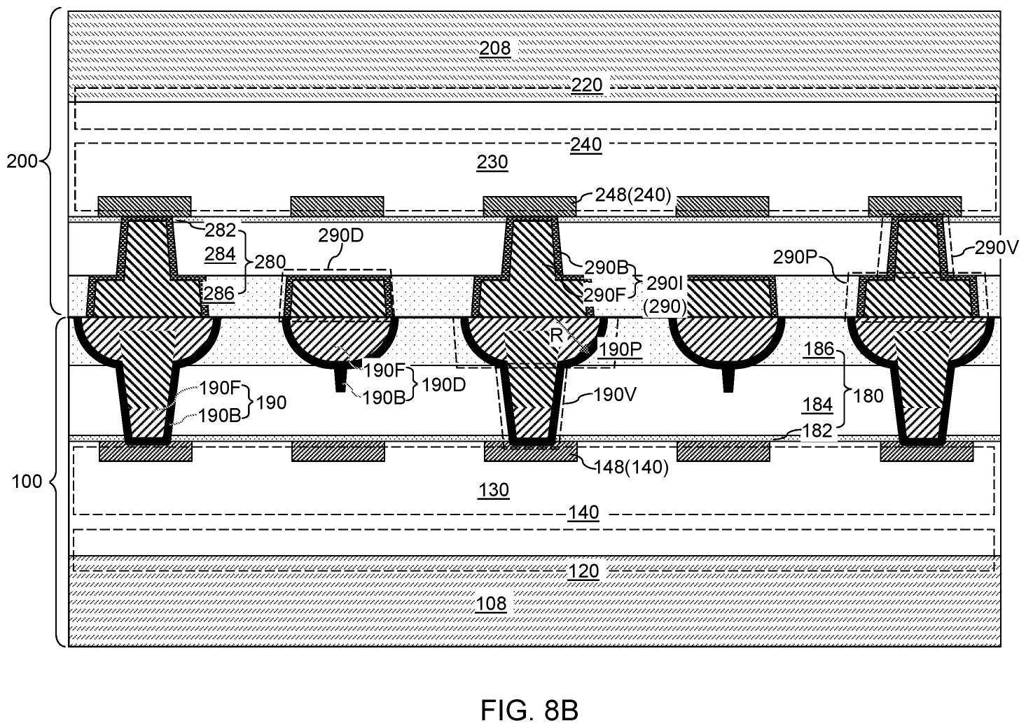

Referring to FIG. 8A, another configuration for the second semiconductor die 200 is illustrated. In this case, the metallic pad portions 290P of the second metal bonding pads 290 may be formed with straight sidewalls. For example, the second metal bonding pads 290 may be formed employing a dual damascene method. Second dummy bonding pads 290D may be formed may be formed with straight sidewalls in addition to the second metal bonding pads 290.

In this embodiment, each of the second metal bonding pads 290 may comprise a respective metallic via portion 290V that extends through a distal portion of the second bonding-level dielectric layer 280, and a respective metallic pad portion 290P having straight sidewalls that extend through a proximal portion of the second bonding-level dielectric layer 280.

In one embodiment, each of the second metal bonding pads 290 comprises a combination of a second metallic barrier liner 290B and a second metallic fill material portion 290F. In one embodiment, each of the second dummy bonding pads 290D comprises a dummy pad portion and a dummy via portion which comprise a combination of a second metallic barrier liner 290B and a second metallic fill material portion 290F.

In one embodiment, each of the second metal bonding pads 290 comprises a respective metallic via portion 290V that is laterally surrounded by a second silicate glass layer 284 and a respective metallic pad portion 290P that is laterally surrounded by a second silicon carbide nitride layer 286.

Referring to FIG. 8A, another configuration for the second semiconductor die 200 is illustrated. In this case, the metallic pad portions 290P of the second metal bonding pads 290 may be formed with straight sidewalls. For example, the second metal bonding pads 290 may be formed employing a dual damascene method. Second dummy bonding pads 290D may be formed may be formed with straight sidewalls in addition to the second metal bonding pads 290.

Referring to FIG. 8A, another configuration for the second semiconductor die 200 is illustrated. In this case, the metallic pad portions 290P of the second metal bonding pads 290 may be formed with straight sidewalls. For example, the second metal bonding pads 290 may be formed employing a dual damascene method. Second dummy bonding pads 290D may be formed may be formed with straight sidewalls in addition to the second metal bonding pads 290.

In this embodiment, each of the second metal bonding pads 290 may comprise a respective metallic via portion 290V that extends through a distal portion of the second bonding-level dielectric layer 280, and a respective metallic pad portion 290P having straight sidewalls that extend through a proximal portion of the second bonding-level dielectric layer 280. In one embodiment, each of the second metal bonding pads 290 comprises a combination of a second metallic barrier liner 290B and a second metallic fill material portion 290F. In one embodiment, each of the second dummy bonding pads 290D comprises a dummy pad portion and a dummy via portion which comprise a combination of a second metallic barrier liner 290B and a second metallic fill material portion 290F. In one embodiment, each of the second metal bonding pads 290 comprises a respective metallic via portion 290V that is laterally surrounded by a second silicate glass layer 284 and a respective metallic pad portion 290P that is laterally surrounded by a second silicon carbide nitride layer 286.

Referring to FIG. 8B, the second semiconductor die 200 described with reference to FIG. 8A may be bonded to the first semiconductor die 100 described with reference to FIG. 7I or to the first semiconductor die 100 described with reference to FIG. 7L, for example, by metal-to-metal bonding. An eighth bonded assembly is formed.

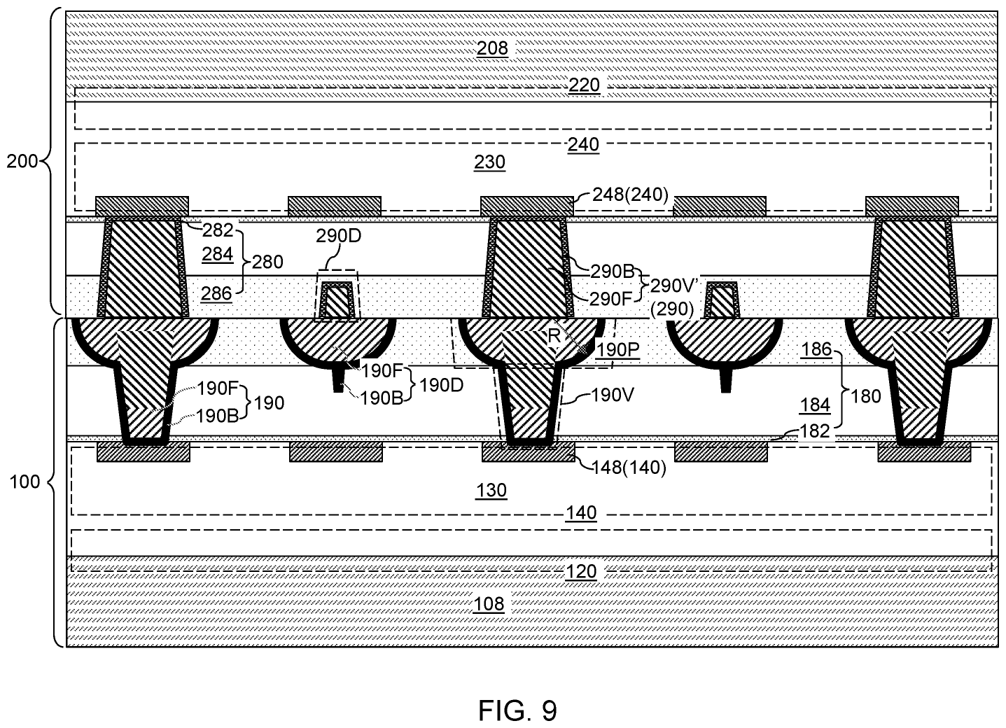

Referring to FIG. 9, a ninth bonded assembly of a first semiconductor die 100 and a second semiconductor die 200 is illustrated. The ninth bonded assembly may be derived from the seventh bonded assembly or the eighth bonded assembly described above by employing via bonding pads 290V and dummy via bonding pads 290DV as the second metal bonding pads 290 and second dummy bonding pads 290D. In this case, each second metal bonding pad 290 may consist of a metallic via portion 290V′, and does not include any metallic pad portion. Each metallic via portion 290V′ may comprise a combination of a second metallic barrier liner 290B (which is a patterned portion of a conductive metallic barrier material) and a second metallic fill material portion 290F (which is a patterned portion of a metallic fill material). In some embodiments, second dummy bonding pads 290D may be provided, for example, by reducing the size of via cavities that is formed in the second bonding-level dielectric layer 280 and by filling the via cavities of the reduced size with the materials of the second metallic barrier liners 290B and the second metallic fill material portions 290F. The second metal bonding pads 290 may be bonded to the first integrated metal bonding pads 190 by metal-to-metal bonding. The second dummy bonding pads 290D may be bonded to the first dummy bonding pads 190D by metal-to-metal bonding.

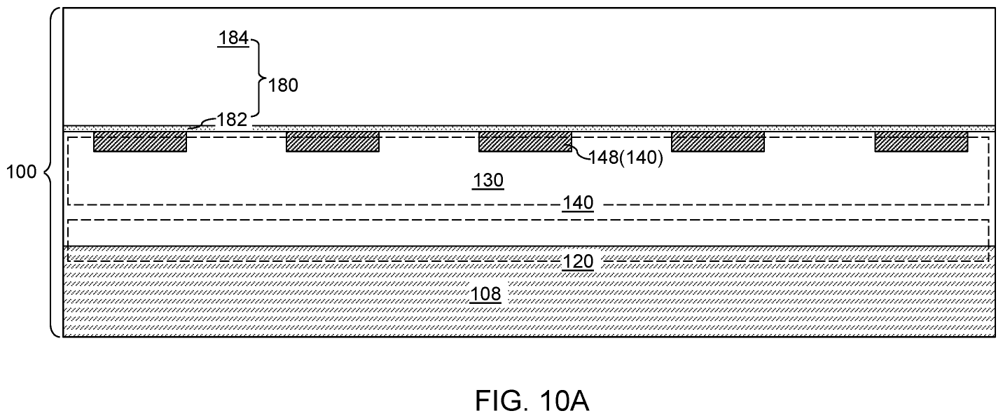

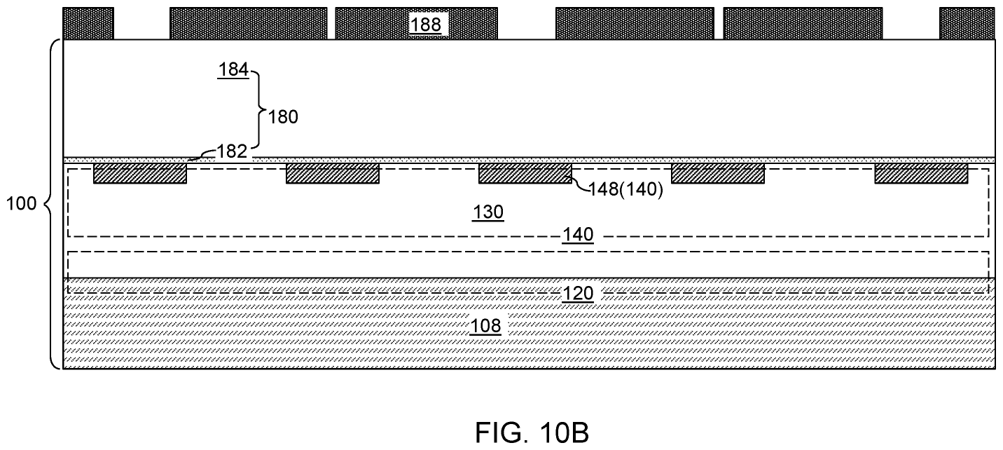

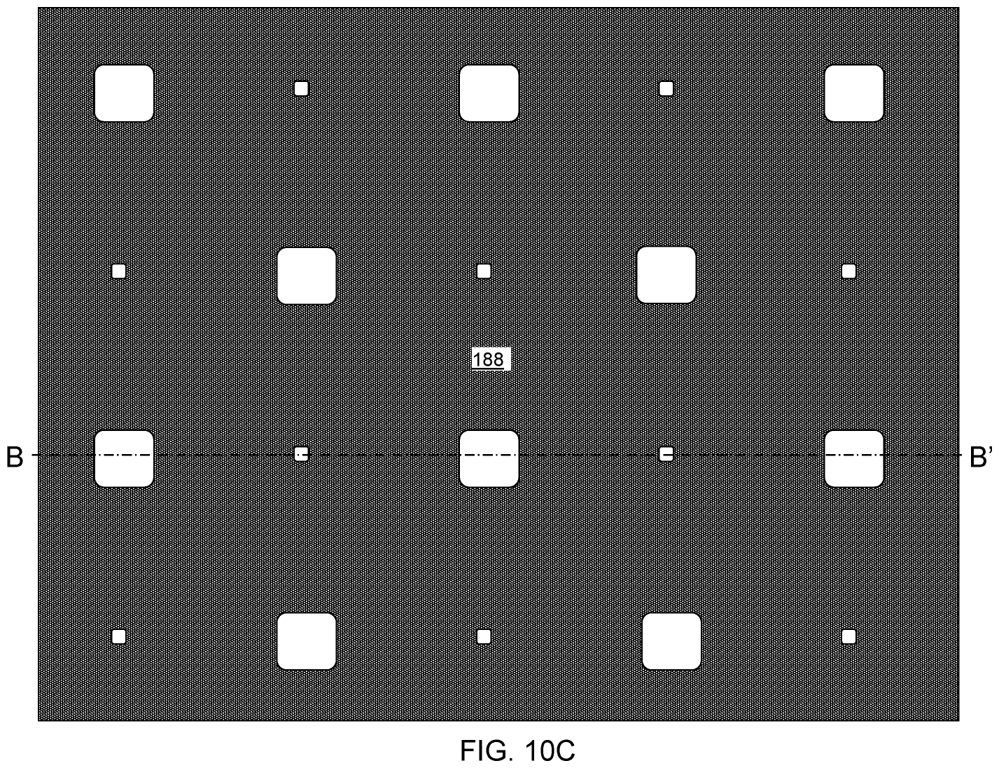

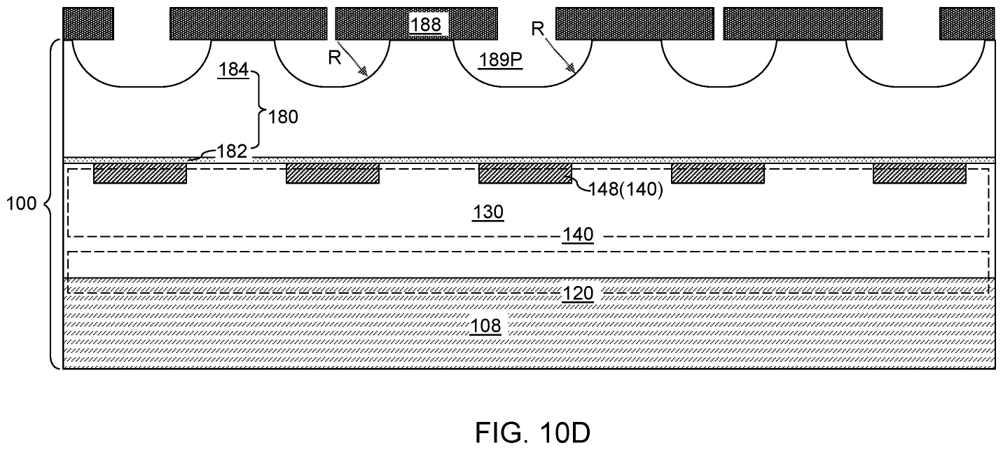

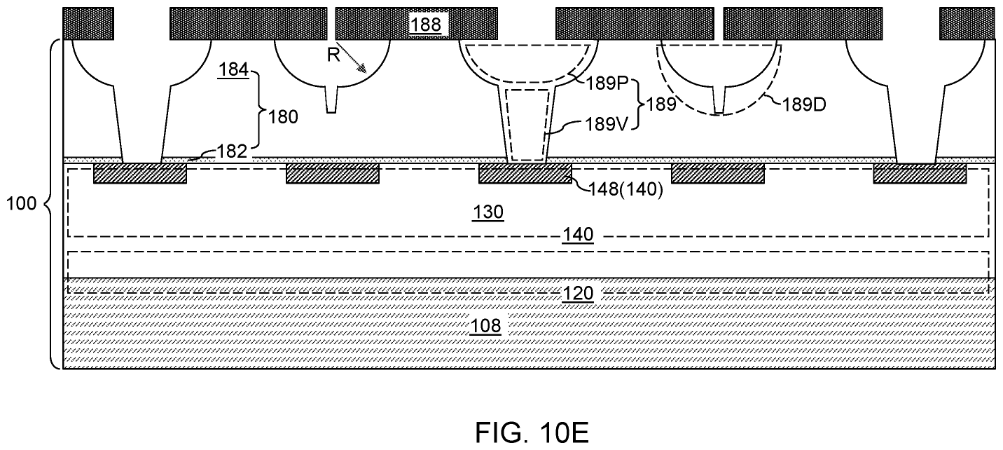

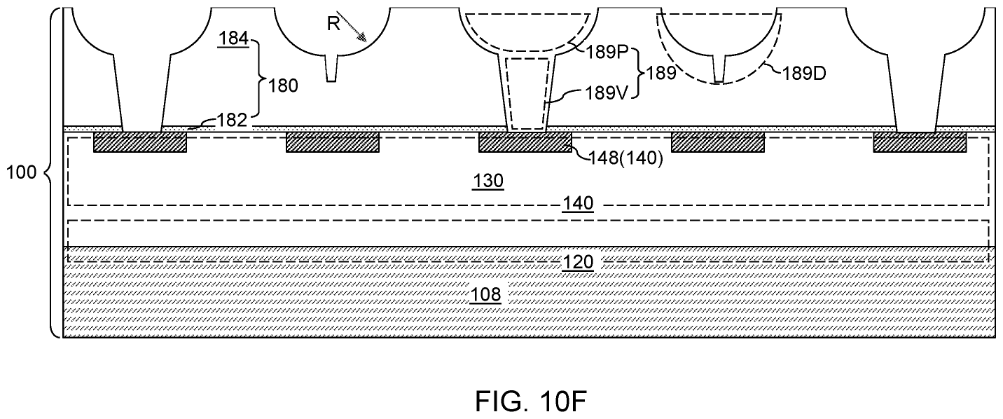

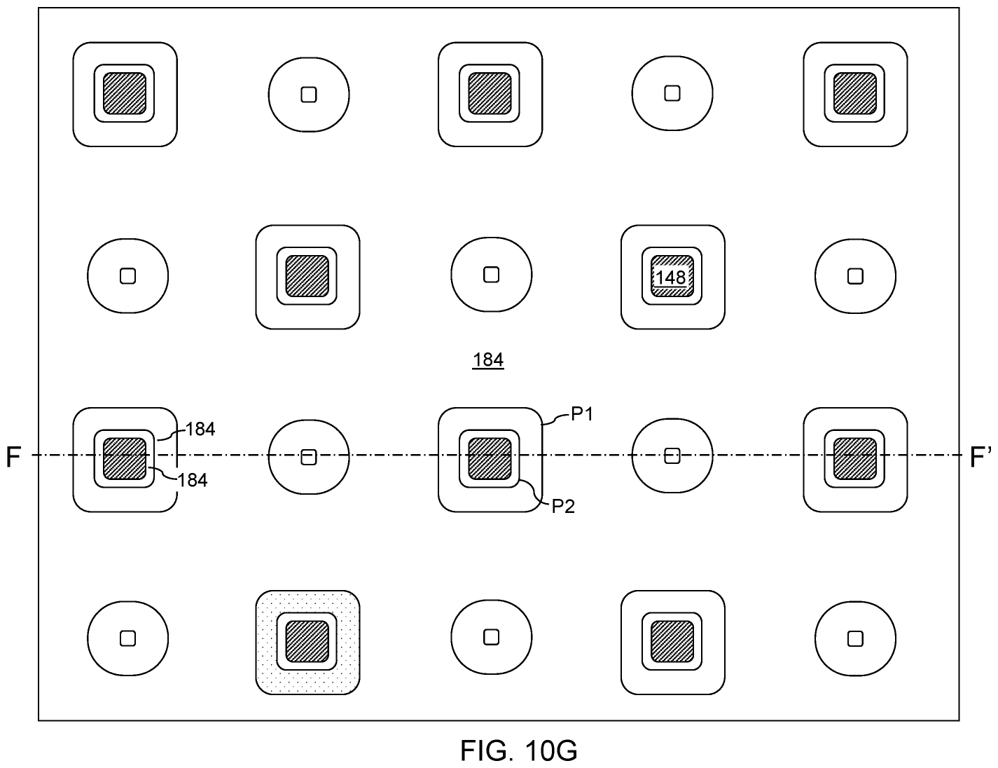

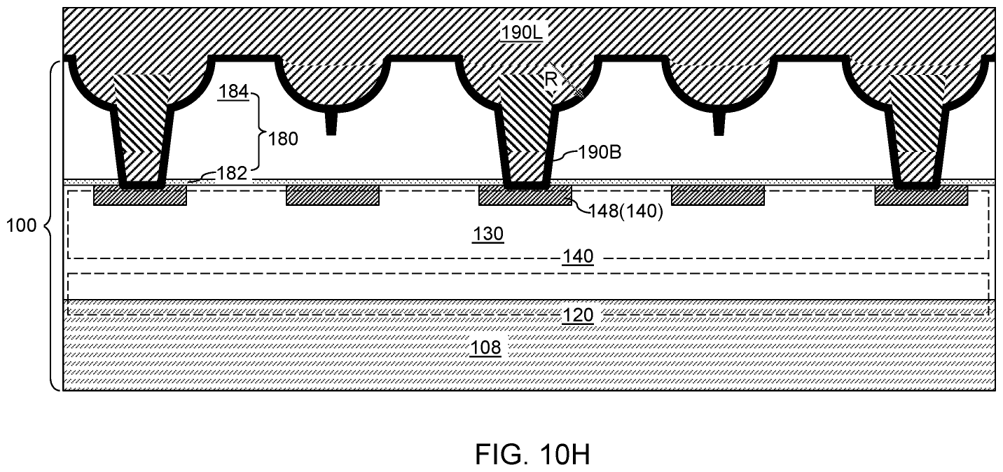

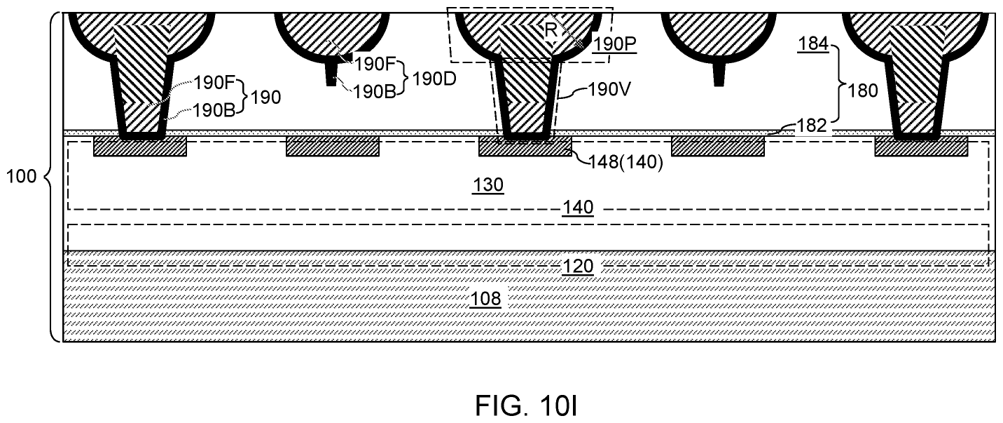

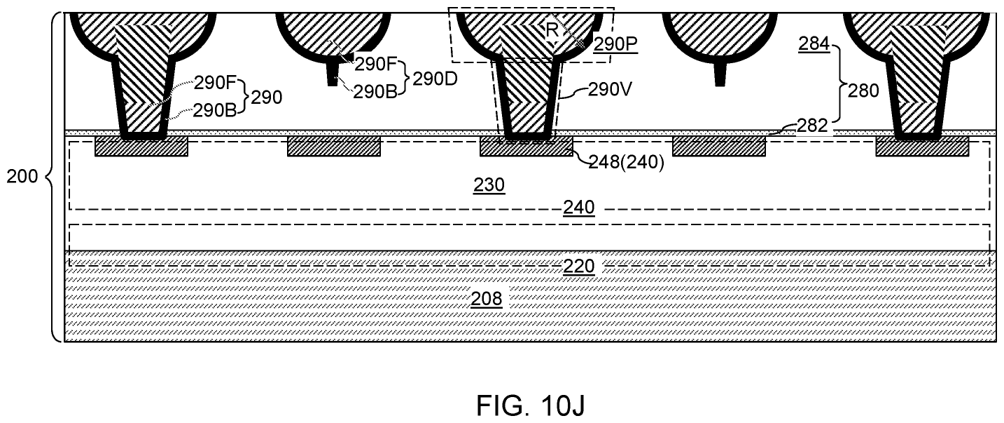

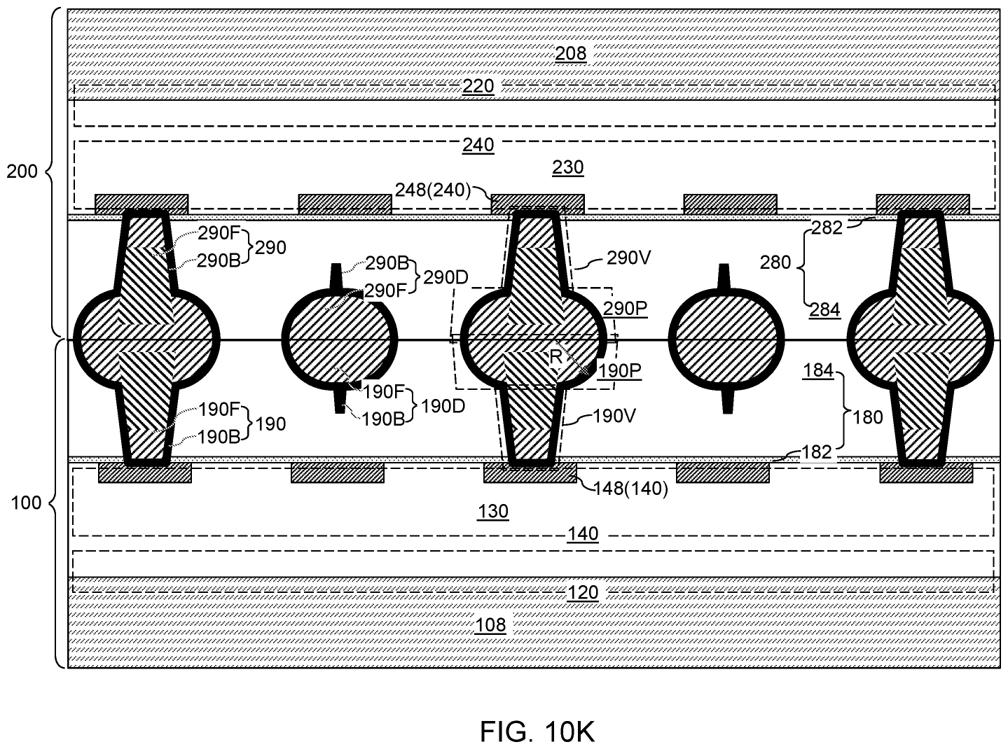

FIGS. 10A, 10B, 10D, 10E, 10F, 10H, and 10I are sequential vertical cross-sectional views of a tenth exemplary structure during formation of a tenth bonded assembly of a first semiconductor die 100 and a second semiconductor die 200 according to an embodiment of the present disclosure. FIG. 10C is a top-down view of the first exemplary structure of FIG. 10B. The vertical plane B-B′ in FIG. 10C is the cut plane of the vertical cross-sectional view of FIG. 10B. FIG. 10G is a top-down view of the first exemplary structure of FIG. 10F. The vertical plane F-F′ in FIG. 10G is the cut plane of the vertical cross-sectional view of FIG. 10F. FIG. 10J is a vertical cross-sectional view of a second semiconductor die 200. FIG. 10K is a vertical cross-sectional view of the fourth bonded assembly of the first semiconductor die 100 and the second semiconductor die 200. The tenth exemplary structure is the same as the fourth exemplary structure illustrated in FIGS. 4A-4K, except that additional dummy bonding pads of the seventh exemplary structure are provided in the tenth exemplary structure.

Referring collectively to FIGS. 10A-10K, the tenth bonded assembly can be derived from the seventh bonded assembly described with reference to FIGS. 7A-7K by employing a first bonding-level dielectric layer 180 which lacks the silicon carbide nitride layer 186. In this embodiment, the first bonding-level dielectric layer 180 consists of only the first silicate glass layer 184 in the first semiconductor die 100. Optionally, the second bonding-level dielectric layer 280 consists of only the second silicate glass layer 284 in the second semiconductor die 200. The first silicate glass layer 184 may have a top surface within a horizontal plane including top surfaces of the first integrated metal bonding pads 190. The second silicate glass layer 284 may have a top surface within a horizontal plane including top surfaces of the second metal bonding pads 290. Upon bonding of the first integrated metal bonding pads 190 with the second metal bonding pads 290 and concurrent bonding of the first dummy bonding pads 190D with the second dummy bonding pads 290D, the first silicate glass layer 180 may be bonded to the second silicate glass layer 280 by dielectric-to-dielectric bonding (such as silicon oxide-to-silicon oxide bonding).

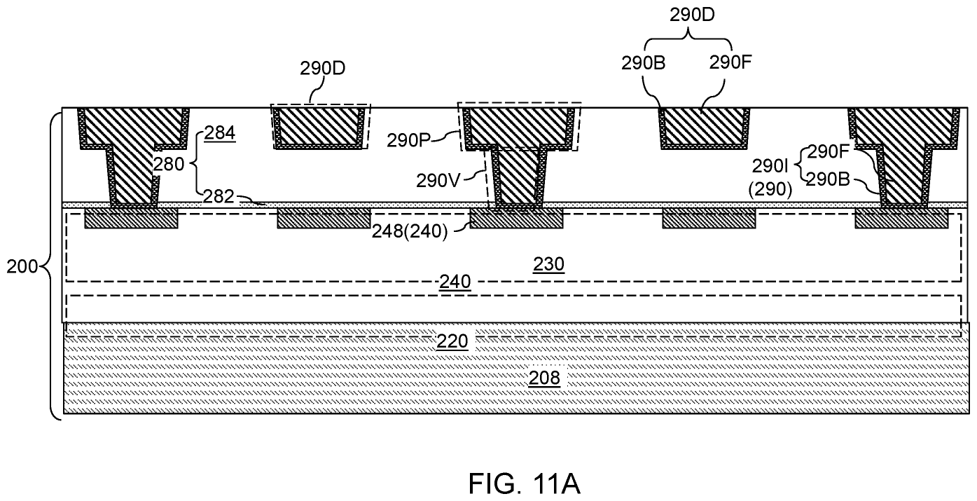

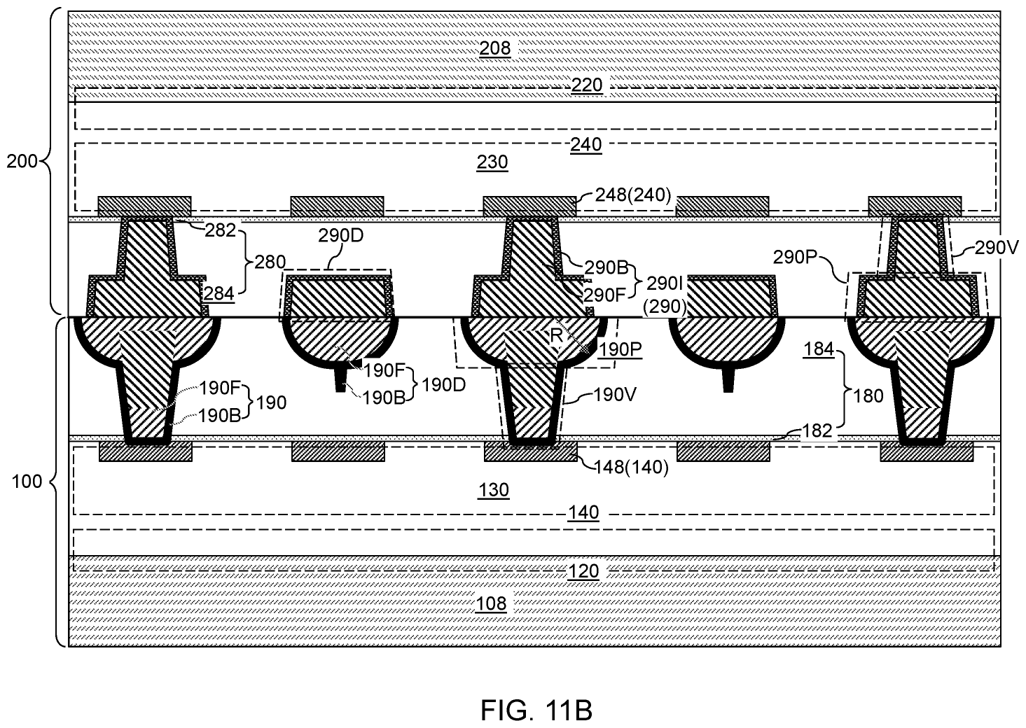

Referring to FIG. 11A, a second semiconductor die 200 for forming an eleventh bonded assembly can be derived from the second semiconductor die 200 illustrated in FIG. 8A by employing a second bonding-level dielectric layer 280 consisting of a second silicate glass layer 284 in the second semiconductor die 200.

Referring to FIG. 11B, an eleventh bonded assembly of a first semiconductor die 100 and the second semiconductor die 200 of FIG. 11A is shown. In the eleventh bonded assembly, the first semiconductor die 100 illustrated in FIG. 10I can be bonded with the second semiconductor die 200 illustrated in FIG. 11A. Upon bonding of the first integrated metal bonding pads 190 with the second metal bonding pads 290 and concurrent bonding of the first dummy bonding pads 190D with the second dummy bonding pads 290D, the first silicate glass layer 180 may be bonded to the second silicate glass layer 280 by dielectric-to-dielectric bonding (such as silicon oxide-to-silicon oxide bonding).

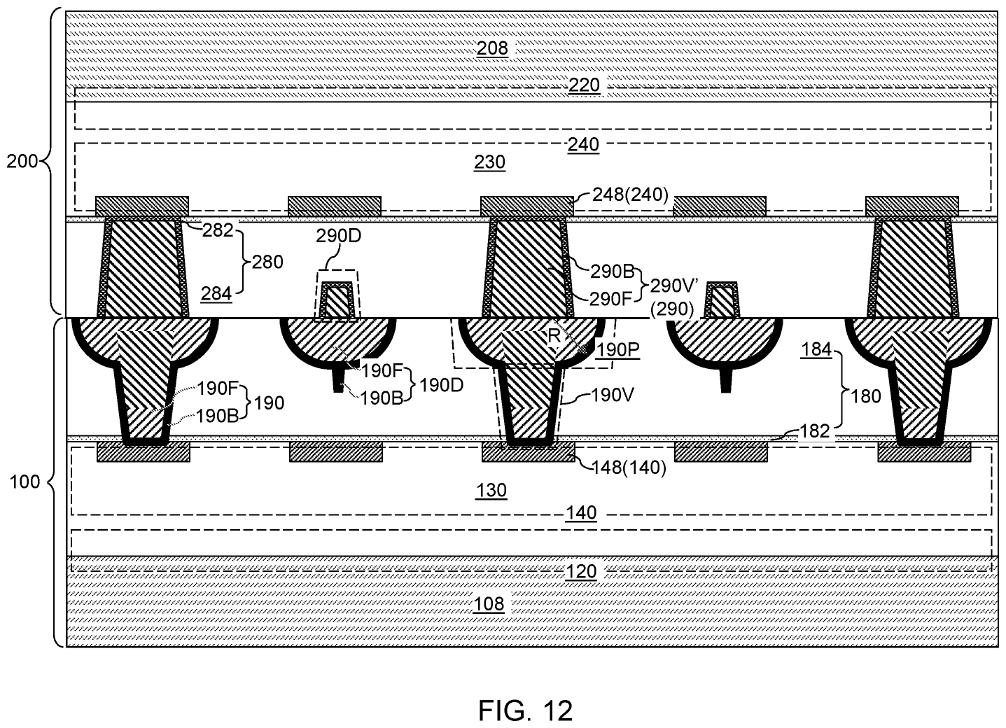

Referring to FIG. 12, a twelfth bonded assembly of a first semiconductor die 100 and a second semiconductor die 200 is illustrated. The twelfth bonded assembly may be derived from the tenth bonded assembly or the eleventh bonded assembly described above by employing via metal bonding pads as second metal bonding pads 290 and as second dummy bonding pads 290D. In this case, each second metal bonding pad 290 may consist of a metallic via portion 290V′, and does not include any metallic pad portion. Each metallic via portion 290V′ may comprise a combination of a second metallic barrier liner 290B (which is a patterned portion of a conductive metallic barrier material) and a second metallic fill material portion 290F (which is a patterned portion of a metallic fill material). Upon bonding of the first integrated metal bonding pads 190 with the second metal bonding pads 290 and concurrent bonding of the first dummy bonding pads 190D with the second dummy bonding pads 290D, the first silicate glass layer 180 may be bonded to the second silicate glass layer 280 by dielectric-to-dielectric bonding (such as silicon oxide-to-silicon oxide bonding).

Referring to all drawings and according to various embodiments of the present disclosure, a semiconductor structure comprising a first semiconductor die 100 is provided. The first semiconductor die 100 comprises: first semiconductor devices 120 located over a first substrate 108; first metal interconnect structures 140 embedded in first dielectric material layers 130 that overlie the first semiconductor devices 120; a first bonding-level dielectric layer 180 that overlies the first dielectric material layers 130; and an array of first integrated metal bonding pads 190 embedded within the first bonding-level dielectric layer 180 and electrically connected to a respective one of the first metal interconnect structures 140, wherein each of the first integrated metal bonding pads 190 comprises: a respective metallic via portion 190V that extends through a lower portion of the first bonding-level dielectric layer 180; and a respective metallic pad portion 190P having a convex sidewall that extends through an upper portion of the first bonding-level dielectric layer 180.

In one embodiment, the convex sidewall of the respective metallic pad portion 190P has a uniform radius of curvature R throughout. In one embodiment, centers of curvature of the convex sidewall of the respective metallic pad portion 190P are located entirely within a horizontal plane including a top surface of the first bonding-level dielectric layer 180.

In one embodiment, the convex sidewall has a bottom periphery that coincides with a top periphery of the respective metallic via portion 190V. In one embodiment, the first bonding-level dielectric layer 180 comprises a layer stack that includes a first silicate glass layer 184 and a first silicon carbide nitride layer 186 that overlies the first silicate glass layer 184; and a boundary between the respective metallic via portion 190V and the respective metallic pad portion 190P is located entirely within the first silicon carbide nitride layer 186.

In one embodiment, the respective metallic pad portion 190P comprises an annular planar bottom surface having an inner periphery that coincides with a top periphery of the respective metallic via portion 190V. In one embodiment, an outer periphery of the annular planar bottom surface coincides with a bottom periphery of the convex sidewall. In one embodiment, the first bonding-level dielectric layer 180 comprises a layer stack that includes a first silicate glass layer 184 and a first silicon carbide nitride layer 186 that overlies the first silicate glass layer 184; and a boundary between the respective metallic via portion 190V and the respective metallic pad portion 190P is located within a horizontal plane including an interface between the first silicate glass layer 184 and the first silicon carbide nitride layer 186.

In one embodiment, the respective metallic via portion 190V has a straight sidewall that extends straight from the top periphery of the respective metallic via portion 190V to a bottom periphery of the respective metallic via portion 190V. In one embodiment, the straight sidewall has a uniform taper angle with respective to a vertical direction in a range from 0.1 degree to 5 degrees.

In one embodiment, first dummy bonding structures have a lesser vertical extent than the first integrated metal bonding pads, are embedded within the first bonding-level dielectric layer and are electrically isolated from the first metal interconnect structures.

In one embodiment, a ratio of a height of the respective metallic pad portion 190P to a height of the respective metallic via portion 190V is in a range from ¼ to 4. In one embodiment, the first integrated metal bonding pads 190 have planar top surfaces within a horizontal plane including a top surface of the first bonding-level dielectric layer 180.

In one embodiment, the first bonding-level dielectric layer 180 consists of a first silicate glass layer 184 having a top surface within a horizontal plane including top surfaces of the first integrated metal bonding pads 190.

In one embodiment, the semiconductor structure comprises a second semiconductor die 200 that is bonded to the first semiconductor die 100. The second semiconductor die 200 comprises: second semiconductor devices 220 located over a second substrate 208; second metal interconnect structures 240 embedded in second dielectric material layers 230 and electrically connected to the second semiconductor devices 220; a second bonding-level dielectric layer 280 located over the second dielectric material layers 230; and an array of second metal bonding pads 290 embedded within the second bonding-level dielectric layer 280 and electrically connected to a respective one of the second metal interconnect structures 240 and bonded to a respective one of the first integrated metal bonding pads 190 by metal-to-metal bonding.

In one embodiment, each of the second metal bonding pads 290 comprises: a respective metallic via portion 290V that extends through a distal portion of the second bonding- level dielectric layer 280; and a respective metallic pad portion 290P having a convex sidewall that extends through a proximal portion of the second bonding-level dielectric layer 280.

The various embodiments of the present disclosure provide simplified process sequence for forming an array of metal bonding pads. Specifically, the use of the wet etch process prior to use of an anisotropic etch process for formation of the via cavities 189V reduces damage to the topmost metal interconnect structures 148 from the wet etch process chemicals. Furthermore, the duration and depth of the anisotropic etch process for formation of the via cavities 189V is reduced. Finally, the silicon carbide nitride layer 186 is optionally and may be omitted in some embodiments to further simplify the process sequence.

Furthermore, wider pad portions 190P and 290P provide an improved pad to pad overlay. For example, the pad portions 190P and 290P may have a width of greater than 400 nm to provide an improved bonding overlay. In contrast, the narrower via portion 190V provides an improved ability to completely overlay the underlying interconnect structures 148, such that the entire bottom surface of the via portion 190V overlies and contacts the underlying interconnect structures 148. The bottom CD of the via portion may be less than 250 nm, such as 140 to 200 nm for improved contact to the underlying interconnect structures 148 and complete dielectric enclosure of the contact area.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph or in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A semiconductor structure comprising a first semiconductor die, wherein the first semiconductor die comprises:
first semiconductor devices located over a first substrate;
first metal interconnect structures embedded in first dielectric material layers that overlie the first semiconductor devices;
a first bonding-level dielectric layer that overlies the first dielectric material layers; and
an array of first integrated metal bonding pads embedded within the first bonding-level dielectric layer and electrically connected to a respective one of the first metal interconnect structures,
wherein each of the first integrated metal bonding pads comprises:
a respective metallic via portion that extends through a lower portion of the first bonding-level dielectric layer; and
a respective metallic pad portion having a convex sidewall that extends through an upper portion of the first bonding-level dielectric layer.

2. The semiconductor structure of claim 1, wherein the convex sidewall of the respective metallic pad portion has a uniform radius of curvature throughout.

3. The semiconductor structure of claim 2, wherein centers of curvature of the convex sidewall of the respective metallic pad portion are located entirely within a horizontal plane including a top surface of the first bonding-level dielectric layer.

4. The semiconductor structure of claim 1, wherein the convex sidewall has a bottom periphery that coincides with a top periphery of the respective metallic via portion.

5. The semiconductor structure of claim 4, wherein:
the first bonding-level dielectric layer comprises a layer stack that includes a first silicate glass layer and a first silicon carbide nitride layer that overlies the first silicate glass layer; and
a boundary between the respective metallic via portion and the respective metallic pad portion is located entirely within the first silicon carbide nitride layer.

6. The semiconductor structure of claim 1, wherein the respective metallic pad portion comprises an annular planar bottom surface having an inner periphery that coincides with a top periphery of the respective metallic via portion.

7. The semiconductor structure of claim 6, wherein an outer periphery of the annular planar bottom surface coincides with a bottom periphery of the convex sidewall.

8. The semiconductor structure of claim 6, wherein:
the first bonding-level dielectric layer comprises a layer stack that includes a first silicate glass layer and a first silicon carbide nitride layer that overlies the first silicate glass layer; and
a boundary between the respective metallic via portion and the respective metallic pad portion is located within a horizontal plane including an interface between the first silicate glass layer and the first silicon carbide nitride layer.

9. The semiconductor structure of claim 1, wherein:
the respective metallic via portion has a straight sidewall that extends straight from the top periphery of the respective metallic via portion to a bottom periphery of the respective metallic via portion; and
the straight sidewall has a uniform taper angle with respective to a vertical direction in a range from 0.1 degree to 5 degrees.

10. The semiconductor structure of claim 1, further comprising first dummy bonding structures having a lesser vertical extent than the first integrated metal bonding pads, embedded within the first bonding-level dielectric layer and electrically isolated from the first metal interconnect structures.

11. The semiconductor structure of claim 1, wherein a ratio of a height of the respective metallic pad portion to a height of the respective metallic via portion is in a range from ¼ to 4.

12. The semiconductor structure of claim 1, wherein the first integrated metal bonding pads have planar top surfaces within a horizontal plane including a top surface of the first bonding-level dielectric layer.

13. The semiconductor structure of claim 1, wherein the first bonding-level dielectric layer consists of a first silicate glass layer having a top surface within a horizontal plane including top surfaces of the first integrated metal bonding pads.

14. The semiconductor structure of claim 1, further comprising a second semiconductor die that is bonded to the first semiconductor die, wherein the second semiconductor die comprises:
second semiconductor devices located over a second substrate;
second metal interconnect structures embedded in second dielectric material layers and electrically connected to the second semiconductor devices;
a second bonding-level dielectric layer located over the second dielectric material layers; and
an array of second metal bonding pads embedded within the second bonding-level dielectric layer and electrically connected to a respective one of the second metal interconnect structures and bonded to a respective one of the first integrated metal bonding pads by metal-to-metal bonding.

15. The semiconductor structure of claim 14, wherein each of the second metal bonding pads comprises:
a respective metallic via portion that extends through a distal portion of the second bonding-level dielectric layer; and
a respective metallic pad portion having a convex sidewall that extends through a proximal portion of the second bonding-level dielectric layer.

16. A method of forming a semiconductor structure, comprising:
forming first semiconductor devices over a first substrate;
forming first dielectric material layers embedding first metal interconnect structures over the first semiconductor devices, wherein the first metal interconnect structures are electrically connected to the first semiconductor devices;
forming a first bonding-level dielectric layer over the first dielectric material layer;
forming an etch mask layer comprising an array of discrete openings therethrough over the first bonding-level dielectric material layer;
forming pad cavities in an upper portion of the first bonding-level dielectric layer underneath the openings in the etch mask layer by performing an isotropic etch process;
forming via cavities in a lower portion of the first bonding-level dielectric layer by performing an anisotropic etch process through the pad cavities while the etch mask layer is present;
removing the etch mask layer; and
forming an array of first integrated metal bonding pads within a combination of the pad cavities and the via cavities.

17. The method of claim 16, wherein each of the first integrated metal bonding pads comprises:
a respective metallic via portion that is formed within a respective one of the via cavities; and
a respective metallic pad portion that is formed within a respective one of the pad cavities.

18. The method of claim 16, wherein the first bonding-level dielectric layer comprises a layer stack that includes a first silicate glass layer and a first silicon carbide nitride layer that overlies the first silicate glass layer.

19. The method of claim 18, wherein the isotropic etch process etches the first silicon carbide nitride layer selective to the first silicate glass layer.

20. The method of claim 16, further comprising:
providing a second semiconductor die which comprises:
second semiconductor devices located over a second substrate,
second metal interconnect structures embedded in second dielectric material layers and electrically connected to the second semiconductor devices,
a second bonding-level dielectric layer located on the second dielectric material layers, and
an array of second metal bonding pads embedded within the second bonding-level dielectric layer and electrically connected to a respective one of the second metal interconnect structures; and
bonding the second metal bonding pads to the first integrated metal bonding pads by metal-to-metal bonding.
